(19) United States
(12) Patent Application Publication
(10) Pub. No.: US 2011/0192446 A1
(43) Pub. Date: Aug. 11, 2011

(54) SOLAR CELL MODULE AND SOLAR PANEL

(75) Inventors: Shoichi KAWAI, Kuwana-city (JP); Susumu Sobue, Obu-city (JP); Yuji Kimura, Nagoya-city (JP)

(73) Assignee: DENSO CORPORATION, Kariya-city (JP)

(21) Appl. No.: 13/020,047

(22) Filed: Feb. 3, 2011

(30) Foreign Application Priority Data
Feb. 5, 2010 (JP) 2010-24355
Feb. 5, 2010 (JP) 2010-24356
Feb. 5, 2010 (JP) 2010-24357

(51) Int. Cl. H01L 31/0232; H01L 31/052; H01L 31/055

(52) U.S. Cl. 136/247; 136/257

(57) ABSTRACT

A solar cell module includes a solar cell and a wavelength conversion optical plate. The solar cell is attached on the optical plate in a thickness direction of the optical plate. The optical plate converts wavelength of solar light. An end portion of the optical plate in a planar direction thereof has an end face inclined relative to the planar direction, so that light, whose wavelength is converted in the optical plate, enters into the solar cell. A solar panel includes a frame and the solar cell modules. The solar cell modules are arranged in the frame in a planar direction of the frame. The frame includes a fixing part, to which an end portion of each of the solar cell modules in a planar direction thereof is fixed in a state where each of the solar cell modules is arranged at a corresponding predetermined fixing position of the frame.

### CROSS REFERENCE TO RELATED APPLICATION

This application is based on and incorporates herein by reference Japanese Patent Application No. 2010-24356 filed on Feb. 5, 2010, Japanese Patent Application No. 2010-24357 filed on Feb. 5, 2010, and Japanese Patent Application No. 2010-24355 filed on Feb. 5, 2010.

### BACKGROUND OF THE INVENTION

1. Field of the Invention

The present invention relates to a solar cell module that improves photoelectric conversion efficiency of a solar cell. Furthermore, the present invention relates to a solar panel in which solar cells are arranged.

2. Description of Related Art

A solar cell that generates electricity by light, such as solar light, does not have the same electric generation effect on the entire wavelength band of light, and the most efficient wavelength band is limited to some extent due to characteristics of its material itself. Accordingly, in the pursuit of efficiency of the solar cell, an available wavelength band tends to be inevitably narrow.

Therefore, a multilayered solar cell (tandem type solar cell) that seeks to widen the available wavelength band by forming solar cells that are made of materials whose most efficient wavelength bands are different, into shapes of thin films, and by stacking these layers of solar cells, is proposed.

Moreover, a solar cell module (see JP-B-08-004147) that makes light enter into the solar cell after converting its wavelength from a low-generation efficiency wavelength into a high-generation efficiency wavelength through the wavelength conversion of the light using a fluorescent optical plate (a fluorescent material is mixed therein), or using a base material obtained as a result of applying fluorochrome to a glass substrate, is proposed.

In addition, a solar cell module (see JP-A-57-095675) in which a solar cell is attached on an end face of the above-described optical plate (wavelength conversion optical plate) that can convert wavelength, and which is configured to concentrate light into the solar cell on the end face of the optical plate by a wave-guiding effect (total reflection) of the optical plate, is proposed.

However, the above-described multilayered solar cell has a limitation in multilayering. Furthermore, a high-cost material such as a germanium (Ge) substrate needs to be employed. Moreover, because a gallium arsenide (GaAs) film is used, the multilayered solar cell has a problem of toxicity. Additionally since the multilayer film is formed, there is a problem of high production costs.

In the solar cell module in which the fluorescent optical plate or the optical plate obtained as a result of applying the fluorochrome to the glass substrate is disposed at an upper portion of the solar cell, when solar light enters, a part of the light whose wavelength is converted enters into the solar cell at a lower portion of the module. Nevertheless, there is much light concentrated in a direction of the end face, and accordingly, there is a small amount of light entering into the solar cell at the lower portion.

In order to improve this, the solar cell module in which the solar cell is attached on an end face of the optical plate is proposed. However, it requires shaping into a strip of the solar cell. Moreover, an advanced technology for the attachment on the end face is necessary, and thereby the production costs become high.

The solar cell is used not only as a solar cell alone but also as a solar panel in which solar cells are arranged in the direction of a plane (see JP-A-51-110985).

In the case of production of this solar panel, because the solar cell has a small thickness of 150 μm to 200 μm, the following operations are performed: the solar cell is attached on a base material of strengthened glass; its surface is filled with resin; the surface is covered with a resin sheet; and it is fitted into a frame made from aluminum, for example.

However, for the production of the solar panel using the solar cell, as described above, operations such as the attachment of the solar cell, the filling of resin, the covering in the resin sheet, and the fixation to the frame are necessary. Therefore, the process of operation is complicated, and the production costs thereby increase.

### SUMMARY OF THE INVENTION

The present invention addresses at least one of the above disadvantages.

According to the present invention, there is provided a solar cell module including a solar cell and a wavelength conversion optical plate. The solar cell has a shape of a flat plate. The optical plate is stacked on the solar cell such that the solar cell is attached on the optical plate in a thickness direction of the optical plate. The optical plate is configured to convert wavelength of solar light. An end portion of the optical plate in a planar direction of the optical plate has an end face which is inclined relative to the planar direction, so that light, whose wavelength is converted in the optical plate, enters into the solar cell.

According to the present invention, there is also provided a solar cell module including a wavelength conversion optical plate and a solar cell. The optical plate is configured to convert wavelength of solar light. An end portion of the optical plate in a planar direction of the optical plate has an end face which is inclined relative to the planar direction. The solar cell has a shape of a flat plate, and is attached on a surface of the inclined end face of the optical plate.

According to the present invention, there is further provided a plate-shaped solar panel including a frame and a plurality of solar cell modules. The plurality of solar cell modules are arranged in the frame in a planar direction of the frame. Each of the plurality of solar cell modules includes a solar cell and a wavelength conversion optical plate. The solar cell has a shape of a flat plate. The optical plate is stacked on the solar cell such that the solar cell is attached on the optical plate in a thickness direction of the optical plate. The optical plate is configured to convert wavelength of solar light. An end portion of the optical plate in a planar direction of the optical plate has an end face which is inclined relative to the planar direction so that light, whose wavelength is converted in the optical plate, enters into the solar cell. The frame includes a fixing part, to which an end portion of each of the plurality of solar cell modules in a planar direction thereof is fixed in a state where each of the plurality of solar cell modules is arranged at a corresponding predetermined fixing position of the frame.

### BRIEF DESCRIPTION OF THE DRAWINGS

The invention, together with additional objectives, features and advantages thereof, will be best understood from the following description the appended claims and the accompanying drawings in which:

FIG. 1 is a diagram illustrating a state in which a solar cell module, in accordance with a first embodiment of the invention is cut in its thickness direction;

FIG. 2A is a perspective view illustrating the solar cell module in accordance with the first embodiment;

FIG. 2B is a plan view illustrating a solar cell module in accordance with a second embodiment of the invention;

FIG. 2C is a bottom view illustrating a solar cell module in accordance with a third embodiment of the invention;

FIG. 3 is a graph illustrating a spectral sensitivity characteristic of a solar cell in accordance with the first embodiment;

FIG. 4A is a diagram schematically illustrating a state in which the solar cell module in accordance with the second embodiment is cut in its thickness direction;

FIG. 4B is a diagram schematically illustrating a state in which the solar cell module in accordance with the third embodiment is cut in its thickness direction;

FIG. 4C is a diagram schematically illustrating a state in which a solar cell module in accordance with a fourth embodiment of the invention is cut in its thickness direction;

FIG. 5A is a diagram schematically illustrating a state in which a solar cell module in accordance with a fifth embodiment of the invention is cut in its thickness direction;

FIG. 5B is a diagram schematically illustrating a state in which a solar cell module in accordance with a sixth embodiment of the invention is cut in its thickness direction;

FIG. 5C is a diagram schematically illustrating a state in which a solar cell module in accordance with a seventh embodiment of the invention is cut in its thickness direction;

FIG. 6A is a diagram schematically illustrating a state in which a solar cell module in accordance with an eighth embodiment of the invention is cut in its thickness direction;

FIG. 6B is a diagram schematically illustrating a state in which a solar cell module in accordance with a ninth embodiment of the invention is cut in its thickness direction;

FIG. 6C is a diagram schematically illustrating a state in which a solar cell module in accordance with a tenth embodiment of the invention is cut in its thickness direction;

FIG. 7A is a diagram schematically illustrating a state in which a solar cell module in accordance with an eleventh embodiment of the invention is cut in its thickness direction;

FIG. 7B is a diagram schematically illustrating a state in which a solar cell module in accordance with a twelfth embodiment of the invention is cut in its thickness direction;

FIG. 8 is a diagram schematically illustrating a state in which a solar panel in accordance with a thirteenth embodiment of the invention is cut (along a line A-A in FIG. 9A) in its thickness direction;

FIG. 9A is a plan view illustrating the solar panel in accordance with the thirteenth embodiment;

FIG. 9B is a bottom view illustrating the solar panel in accordance with the thirteenth embodiment;

FIG. 10A is a perspective view illustrating a solar cell module used in the thirteenth embodiment;

FIG. 10B is a plan view illustrating the solar cell module used in the thirteenth embodiment;

FIG. 11 is a graph illustrating a spectral sensitivity characteristic of a solar cell in accordance with the thirteenth embodiment;

FIG. 12A is a diagram schematically illustrating a state in which a solar panel in accordance with a fourteenth embodiment of the invention is cut (along a line B-B in FIG. 9A) in its thickness direction;

FIG. 12B is an enlarged view illustrating a main feature of a section of a solar cell module in accordance with the fourteenth embodiment;

FIG. 12C is a diagram schematically illustrating a state in which a solar cell module in accordance with a fifteenth embodiment of the invention is cut (along the line A-A in FIG. 9A) in its thickness direction;

FIG. 12D is a diagram schematically illustrating a state in which a solar cell module in accordance with a sixteenth embodiment of the invention is cut (along the line B-B in FIG. 9A) in its thickness direction;

FIG. 13A is a diagram schematically illustrating a state in which a solar panel in accordance with a seventeenth embodiment of the invention is cut (along the line A-A in FIG. 9A) in its thickness direction;

FIG. 13B is a diagram schematically illustrating a state in which a solar panel in accordance with an eighteenth embodiment of the invention is cut (along the line A-A in FIG. 9A) in its thickness direction;

FIG. 13C is a diagram schematically illustrating a state in which a solar cell module in accordance with a nineteenth embodiment of the invention is cut (along the line A-A in FIG. 9A) in its thickness direction;

FIG. 13D is a diagram schematically illustrating a state in which a solar cell module in accordance with a twentieth embodiment of the invention is cut (along the line B-B in FIG. 9A) in its thickness direction;

FIG. 14A is a diagram illustrating a solar cell module of the invention;

FIG. 14B is a diagram illustrating a solar cell module of the invention;

FIG. 14C is a diagram illustrating a solar cell module of the invention;

FIG. 14D is a diagram illustrating a solar cell module of the invention;

FIG. 15 is a diagram illustrating a state in which a solar cell module in accordance with a twenty-first embodiment of the invention is cut in its thickness direction;

FIG. 16A is a perspective view illustrating the solar cell module in accordance with the twenty-first embodiment;

FIG. 16B is a plan view illustrating a solar cell module in accordance with a twenty-second embodiment of the invention;

FIG. 17A is a diagram schematically illustrating a state in which the solar cell module in accordance with the twenty-second embodiment is cut in its thickness direction;

FIG. 17B is a diagram schematically illustrating a state in which a solar cell module in accordance with a twenty-third embodiment of the invention is cut in its thickness direction;

FIG. 17C is a diagram schematically illustrating a state in which a solar cell module in accordance with a twenty-fourth embodiment of the invention is cut in its thickness direction;

FIG. 17D is a diagram schematically illustrating a state in which a solar cell module in accordance with a twenty-fifth embodiment of the invention is cut in its thickness direction;

FIG. 17E is a diagram schematically illustrating a state in which a solar cell module in accordance with a twenty-sixth embodiment of the invention is cut in its thickness direction;

FIG. 18A is a diagram schematically illustrating a state in which a solar cell module in accordance with a twenty-seventh embodiment of the invention is cut in its thickness direction;

FIG. 18B is a diagram schematically illustrating a state in which a solar cell module in accordance with a twenty-eighth embodiment of the invention is cut in its thickness direction;

FIG. 18C is a diagram schematically illustrating a state in which a solar cell module in accordance with a twenty-ninth embodiment of the invention is cut in its thickness direction;

FIG. 18D is a diagram schematically illustrating a state in which a solar cell module in accordance with a thirtieth embodiment of the invention is cut in its thickness direction;

FIG. 19A is a diagram schematically illustrating a state in which a solar cell module in accordance with a thirty-first embodiment of the invention is cut in its thickness direction;

FIG. 19B is a diagram schematically illustrating a state in which a solar cell module in accordance with a thirty-second embodiment of the invention is cut in its thickness direction; and

FIG. 19C is a diagram schematically illustrating a principle of electricity generation by the solar cell module in accordance with the thirty-second embodiment.

### DETAILED DESCRIPTION OF THE INVENTION

Embodiments of a solar cell module of the invention will be described below by, giving some specific examples.

### First Embodiment

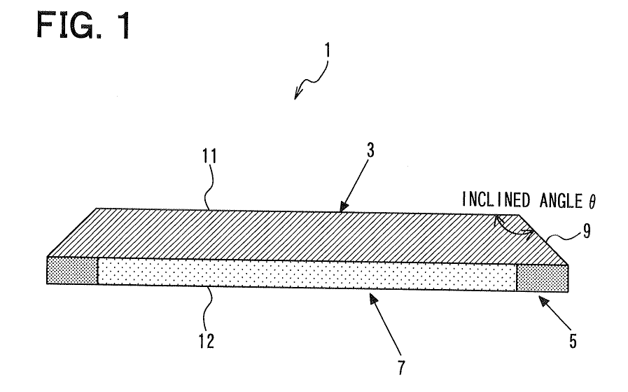

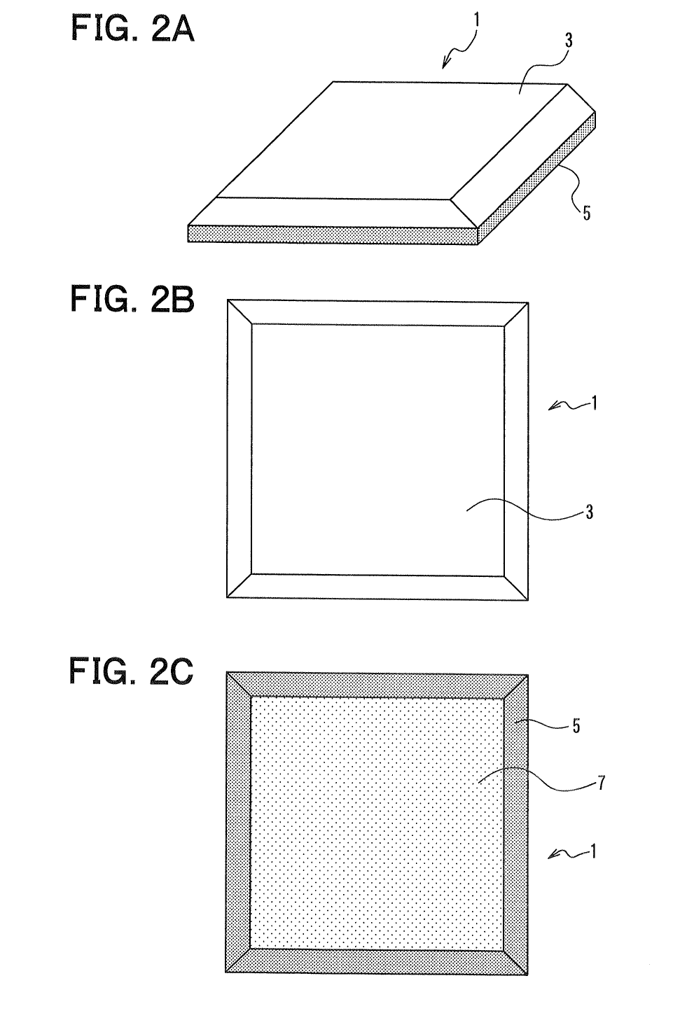

A configuration of a solar cell module of the present embodiment will be described. As illustrated in FIGS. 1 to 2C, a solar cell module 1 of the present embodiment is obtained as a result of attaching a first solar cell 5 having high sensitivity (high photoelectric conversion efficiency) and a second solar cell 7 having lower sensitivity than the first solar cell 5 (low photoelectric conversion efficiency) on one side (lower side in FIG. 1) of a wavelength conversion optical plate 3 whose flat surface shape is a square in its thickness direction by an optical adhesive (e.g., optical silicon resin adhesive) having translucency.

More specifically, the wavelength conversion optical plate 3 is a transparent flat plate having a size of 100 mm longitudinally, 100 mm laterally, and 3 mm in thickness. An end face (four sides) 9 of the plate 3 along the whole circumference in its planar direction (direction perpendicular to the thickness direction) is cut obliquely relative to the planar direction (inclined by 45 degrees, for example) such that the end face 9 is larger on the solar cells 5, 7 side (light outgoing side).

The wavelength conversion optical plate 3 is made of LUMILAS G9 (trade name), for example, and constituted of fluorescent glass (B₂O₃.CaO.SiO₂.La₂O₃.Tb³⁺) with terbium (Tb) added. This wavelength conversion optical plate 3 absorbs light in an ultraviolet region that is equal to or smaller than the wavelength 400 nm of light, and shows fluorescence at a wavelength of 545 nm.

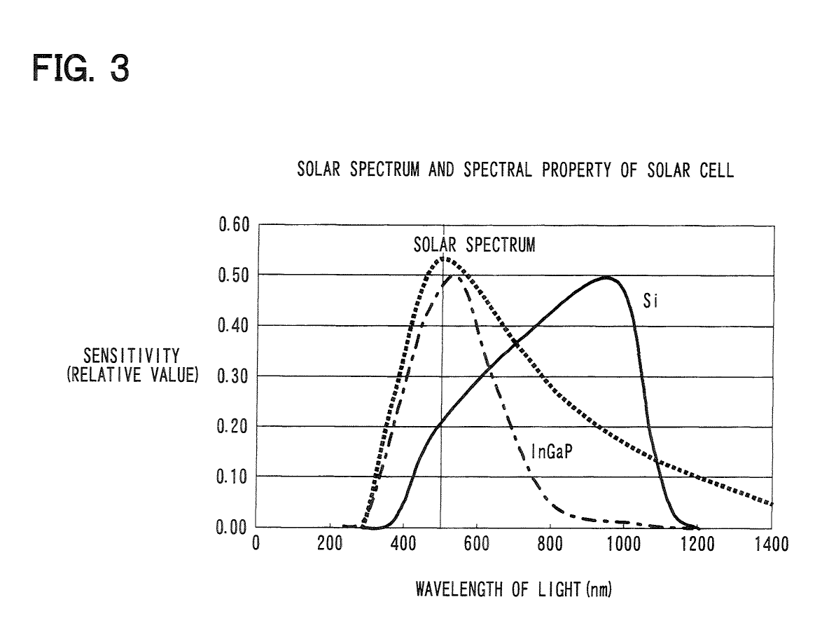

The first solar cell 5 has a frame shape whose flat surface shape is a square (its center portion opens) and which has a size of 100 mm longitudinally on its external side, 100 mm laterally on its external side, 3 mm in thickness, and 3 mm in width of the frame. The first solar cell 5 is an indium gallium phosphide (InGaP) system solar cell having a band gap of 1.9 eV. This first solar cell 5 has a spectral characteristic (spectral sensitivity characteristic) indicated by a dashed-dotted line in FIG. 3, i.e., performance of high sensitivity in photoelectric conversion at a wavelength of 550 nm. In FIG. 3, an energy distribution of solar light is schematically indicated by a short dashes line.

The second solar cell 7 is a silicon (Si) single crystal solar cell with a size of 94 mm longitudinally, 94 mm laterally and 3 mm in thickness, whose flat surface shape is a square, and which has a band gap of 1.1 eV (i.e. solar cell having lower sensitivity than the first solar cell 5 to the light whose wavelength is converted). This second solar cell 7 has a spectral characteristic indicated by a continuous line in FIG. 3. As illustrated in FIG. 3, this second solar cell 7 hardly generates electricity in an ultraviolet light area that is equal to or smaller than 400 nm.

Functions of the solar cell module 1 of the present embodiment will be described. In the present embodiment, as illustrated in FIG. 1, a part of solar light which enters from the outside through an upper surface 11 of the solar cell module 1 (incident side of the wavelength conversion optical plate 3) generates a fluorescence of 545 nm at the wavelength conversion optical plate 3. The light (fluorescence) reflects and is concentrated in the wavelength conversion optical plate 3. The light enters into and reflects on the slant end face 9 of the wavelength conversion optical plate 3 that is inclined by 45 degrees. The light is emitted from a lower surface 12 on an emission side of the wavelength conversion optical plate 3, and enters mainly into the first solar cell 5 at an outer circumferential part of the wavelength conversion optical plate 3.

At the same time, incident light (light which is not fluorescence) under the total reflection condition, which enters into the solar cell module 1 from the outside, reflects similarly on the end face 9 and enters mainly into the first solar cell 5. Because of these effects, the photoelectric conversion amount of this portion improves.

Therefore, by limitedly disposing the first solar cell 5 which is high-cost but has high sensitivity (i.e., high photoelectric conversion efficiency), at the region, where the incident amount of light whose wavelength is converted is large, reduction of costs and improvement in photoelectric conversion efficiency are achieved at the same time.

The fluorescence of 545 nm is generated in the wavelength conversion optical plate 3. The light of this fluorescence of 545 nm which does not enter into the end face 9 enters mainly into the second solar cell 7. Accordingly, the amount of photoelectric conversion improves slightly.

Furthermore, since glass which constitutes this wavelength conversion optical plate 3 is transparent, most of the lights from visible light to infrared light permeate the wavelength conversion optical plate 3 and enter into the second solar cell 7 to be photoelectrically converted. Thus, in the present embodiment, as a result of the combination of these three photoelectric conversions, the conversion efficiency of 17.5% for the second solar cell 7 alone improves to the conversion efficiency of 22% for the entire solar cell module 1 (including the first solar cell 5 and the second solar cell 7).

In the case of production of the solar cell module 1 of the present embodiment, both the solar cells 5, 7 only need to be attached in the thickness direction of the wavelength conversion optical plate 3 on the plate 3 with its end face 9 obliquely cut. Accordingly, compared to the conventional technology, the production is very simple, and a special jig or the like is not needed. As a result, there is an advantage of low costs.

The following configurations may be employed for modifications of the present embodiment. The end face 9 may be cut at a slant after both the solar cells 5, 7 and the wavelength conversion optical plate 3 are attached to each other.

Also, as is normally done, a method of cutting a plate material by such as a cutter, or a method of forming through surface polish, for example, may be employed for the method of cutting slantwise the wavelength conversion optical plate 3. Or, when forming the wavelength conversion optical plate 3 made of glass, the wavelength conversion optical plate 3 may be formed within a mold of a target shape.

Glass or resin is employable as the base material for the wavelength conversion optical plate 3. For example, an acrylic board containing Lumogen coloring matter of BASF Co. may, be used. Various kinds of fluorescent materials such as a widely known inorganic fluorescent material (e.g., semiconductor nano fluorescent material) and organic fluorescent material may be used for the fluorescent material contained in the base material.

The invention is configured such that a light within a specific wavelength band is converted into a light having another wavelength by the wavelength conversion optical plate, and the converted light is made to enter into the solar cell. In the invention, because the end face of the wavelength conversion optical plate is obliquely formed, i.e., because the end face is formed (e.g., obliquely cut) such that the end face is inclined relative to the planar direction in a range that is larger than 90 degrees and smaller than 180 degrees (90°<inclined angle θ<180°), the light, which has been wavelength-converted and concentrated in the wavelength conversion optical plate, appropriately reflects on the plate end face toward the solar cell, and enters into the solar cell. Accordingly, photoelectric conversion efficiency in the solar cell module (therefore, generation efficiency) is improved.

In the invention, by only bonding the solar cell (by such as optical adhesive) on the wavelength conversion optical plate in its thickness direction, generation efficiency improves. Accordingly, the solar cell module is easily produced, and the production costs can also be reduced.

Particularly, in the invention, the high-sensitivity first solar cell (e.g., InGaP solar cell: Eg1.9 eV) is arranged on the outer circumferential part (outer edge side opposed to the inclined end face in the thickness direction) of the surface on the side (i.e., solar cell side) on which the light reflected on the inclined end face is emitted from the wavelength conversion optical plate; and the second solar cell (e.g., Si solar cell: Eg1.1 eV) having lower sensitivity than the first solar cell is arranged inward of the outer circumferential part.

Normally, the high-sensitivity solar cell is high-cost. Therefore, in the invention, the high-sensitivity first solar cell is disposed particularly on the outer circumferential part into which the (wavelength-converted) light efficiently enters, and the low-sensitivity second solar cell is disposed inward of the outer circumferential part. Accordingly, reduction of costs and improvement in photoelectric conversion efficiency are achieved at the same time.

For example, an optical plate that is made of transparent glass or resin may be employed for the wavelength conversion optical plate. This optical plate contains a fluorescent material that generates fluorescence in accordance with the solar light which has entered, in the glass or resin.

### Second Embodiment

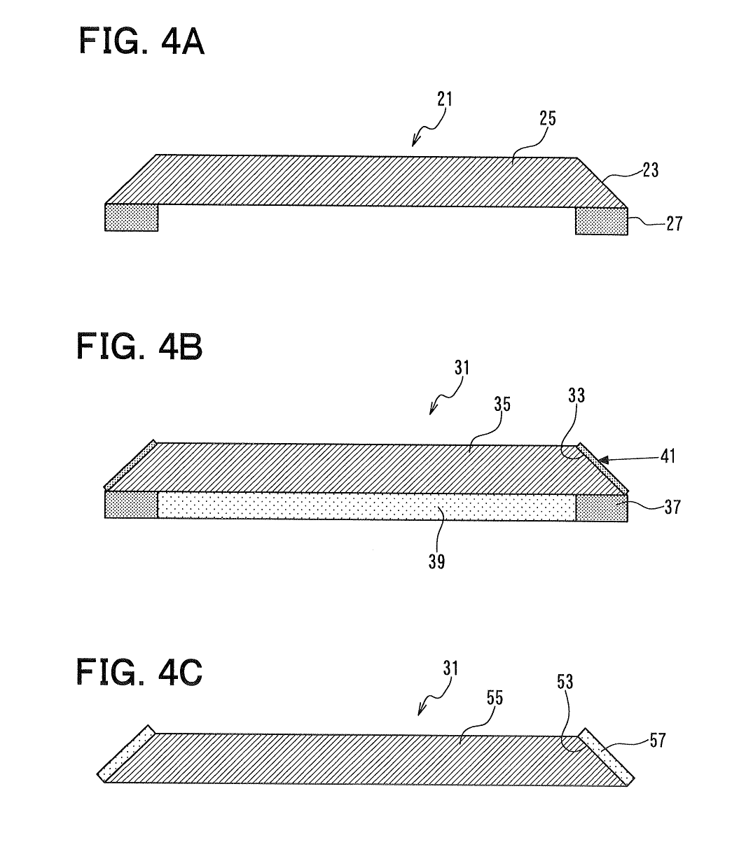

A second embodiment of the invention will be described. Description similar to the first embodiment is omitted. As illustrated in FIG. 4A, similar to the first embodiment, a solar cell module 21 of the present embodiment is obtained, for example, as a result of attaching a solar cell 27 having performance similar to the first solar cell on a wavelength conversion optical plate 25 in a thickness direction of the plate 25 with its end face 23 obliquely cut.

In the present embodiment, the InGaP system solar cell 27 having a quadrilateral frame shape is attached on a light emission side of the wavelength conversion optical plate 25 (lower side in FIG. 4A). The solar cell 27 is not arranged inward of the solar cell 27, and a space is left inward of the cell 27.

In the present embodiment, the solar cell 27 is not arranged inward of the outer circumferential part in the planar direction. Accordingly, the light which enters from the center of the solar cell module 21 permeates the wavelength conversion optical plate 25 to be emitted to the outside without being blocked with the solar cell 27. As a result, heat produced by this light can be used efficiently (e.g., for heating of water).

In the invention, the solar cell is arranged on the outer circumferential part on the side on which the light reflected on the inclined end face is emitted from the wavelength conversion optical plate. Accordingly, high photoelectric conversion efficiency is realized.

### Third Embodiment

A third embodiment of the invention will be described. Description similar to the first embodiment is omitted. As illustrated in FIG. 4B, similar to the first embodiment, a solar cell module 31 of the present embodiment is obtained as a result of attaching a first solar cell 37 having high sensitivity and a square second solar cell 39 having lower sensitivity (than the first solar cell 37) on a wavelength conversion optical plate 35 in a thickness direction of the plate 35 with its end face 33 obliquely cut. Similar to the first embodiment, the first solar cell 37 has a quadrilateral frame shape, and the square second solar cell 39 is disposed inward of the cell 37.

Particularly, in the present embodiment, for example, a reflective film 41 which is made of aluminium and is a thin film that reflects light, is formed such as by evaporation coating or sputtering on an outer surface of the slanted end face 33. Accordingly, in the present embodiment, the light, whose wavelength has been converted in the wavelength conversion optical plate 35 and which has reached the slanted end face 33, is reflected approximately 100% on the end face 33. The light enters efficiently into both the solar cells 37, 39 (particularly, first solar cell 37).

### Fourth Embodiment

A fourth embodiment of the invention will be described. Description similar to the first embodiment is omitted. As illustrated in FIG. 40, similar to the first embodiment, a solar cell module 51 of the present embodiment includes a wavelength conversion optical plate 55 with its end face 53 obliquely cut. In the present embodiment, for example, a solar cell 57 which is an Si single crystal is attached on an outer surface of the inclined end face 53. Accordingly, in the present embodiment, the area of the solar cell 57 is enlarged compared to the conventional case of attachment of the solar cell on the vertical end face. As a result, the production of electricity is increased. In addition, because the area of the solar cell 57 is large, the cell 57 is readily formed.

### Fifth Embodiment

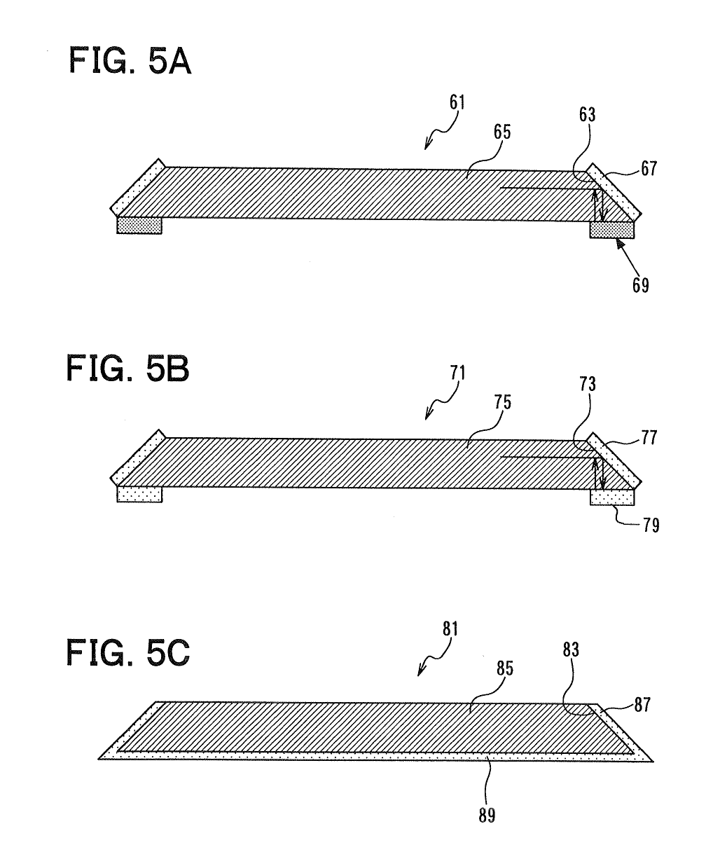

A fifth embodiment of the invention will be described. Description similar to the first embodiment is omitted. As illustrated in FIG. 5A, similar to the fourth embodiment, a solar cell module 61 of the present embodiment includes a wavelength conversion optical plate 65 with its end face 63 obliquely cut, and for example, a solar cell 67 which is an Si single crystal is attached on an outer surface of the slant end face 63.

Particularly, in the present embodiment, on an outer circumferential part of a surface of the wavelength conversion optical plate 65 on a light emission side of the plate 65 (lower side in FIG. 5A), the outer circumferential part being opposed to the oblique end face 63, a reflective film 69 which is made of aluminium, for example, and is a thin film that reflects light, is formed by such as evaporation coating or sputtering.

Accordingly, the leakage of light from the emission-side surface to the outside is prevented, and the light, which has been reflected on the end face 63, is reflected again toward the solar cell 67 on the reflective film 69. As a result, the photoelectric conversion efficiency is increased.

In the invention, the solar cell is attached on the outer surface of the slanted end face, and the reflective film is provided on the outer surface of the wavelength conversion optical plate (that the reflected light reaches) that is opposed to the end face. Accordingly, the leakage of light from the surface (that the reflected light reaches) is prevented, and photoelectric conversion efficiency thus increases.

### Sixth Embodiment

A sixth embodiment of the invention will be described. Description similar to the first embodiment is omitted. As illustrated in FIG. 5B, similar to the fourth embodiment, a solar cell module 71 of the present embodiment includes a wavelength conversion optical plate 75 with its end face 73 obliquely cut, and for example, a solar cell 77 which is an Si single crystal is attached on an outer surface of the slant end face 73.

Particularly, in the present embodiment, a solar, cell 79, which is a similar Si single crystal, for example, is attached also to an outer circumferential part on a surface of the wavelength conversion optical plate 75 on a light emission side (lower side in FIG. 5B) of the plate 75, the outer circumferential part being opposed to the skew end face 73.

Accordingly, the light whose wavelength has been converted enters into the solar cell 77 on the end face 73. The light which has been reflected on the end face 73 enters into the solar cell 79 on the outer circumferential part. Moreover, the light which has been reflected on the surface of the outer circumferential part returns to the end face 73, and enters into the solar cell 77 on the end face 73. As a result, the light whose wavelength has been converted is made to efficiently enter into both the solar cells 77, 79. Thus, photoelectric conversion efficiency of the entire solar cell module 71 improves.

### Seventh Embodiment

A seventh embodiment of the invention will be described. Description similar to the first embodiment is omitted. As illustrated in FIG. 5C, similar to the sixth embodiment, a solar cell module 81 of the present embodiment includes a wavelength conversion optical plate 85 with its end face 83 obliquely cut, and for example, a solar cell 87 which is an Si single crystal is attached on an outer surface of the slant end face 83.

Particularly, in the present embodiment, a solar cell 89, which is a similar Si single crystal, for example, is attached on the entire surface of the wavelength conversion optical plate 85 on the light emission side (lower side in FIG. 5C) in a thickness direction of the plate 85. Accordingly, in the present embodiment, the solar cell 89 is provided not only for the slant end face 83 but also for the entire surface of the light emission side (lower surface). As a result, electricity is generated using the wavelength converted and concentrated light (light wavelength-converted and concentrated on the end face-side), the wavelength converted light (light transmitted in the thickness direction after wavelength conversion), and the optical plate transmitted light (light transmitted without being wavelength-converted). Therefore, optical conversion efficiency improves.

More specifically, when a pseudo solar light of AM 1.5 and 100 mW/cm² is made to enter into this solar cell module 81, thermal conversion efficiency improves from 17.5% (in the case of attachment of the solar cell only on the lower surface) to 21.5%.

### Eighth Embodiment

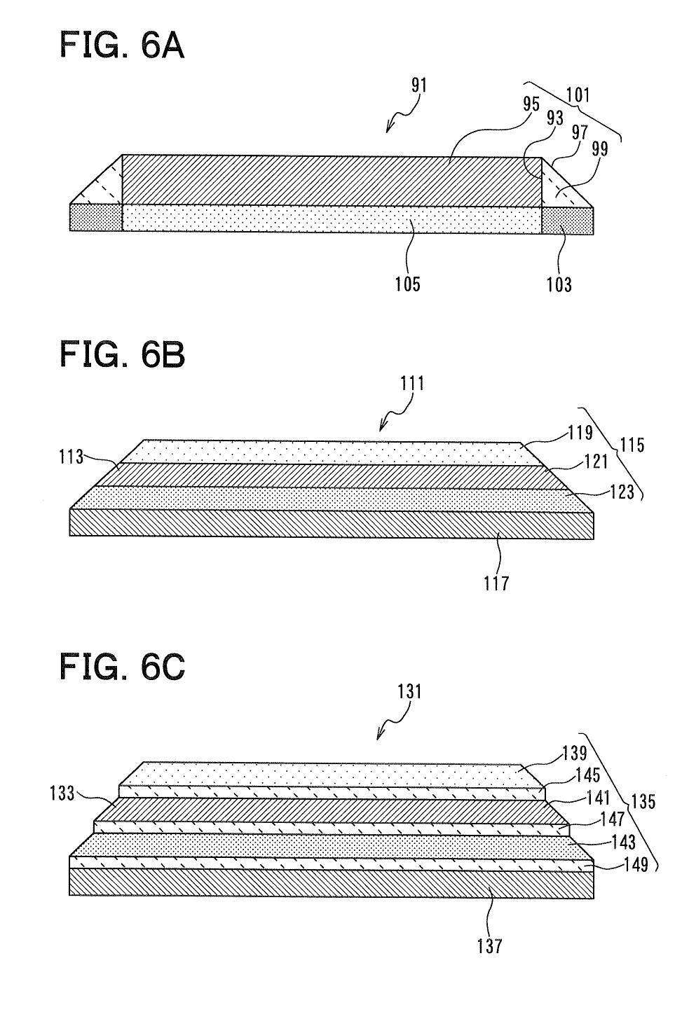

An eighth embodiment of the invention will be described. Description similar to the first embodiment is omitted. As illustrated in FIG. 6A, in a solar cell module 91 of the present embodiment, a triangular prism-shaped optical component (i.e., optical component having an oblique end face 97) 99 made of transparent glass or resin is attached on the end face 93 of the circumference of a square base material 95 that performs the wavelength conversion in the planar direction with its end face 93 perpendicular to the planar direction; and a wavelength conversion optical plate 101 is thereby constituted. In addition, a flat surface shape of the optical component 99 is a quadrilateral frame shape.

A high-sensitivity first solar cell 103 having a quadrilateral frame shape which is similar to the first embodiment is attached on a lower surface of the optical component 99, and a low-sensitivity second solar cell 105 similar to the first embodiment is attached on a lower surface of the base material 95.

Therefore, in the present embodiment, even though the end face 93 of the base material 95 (performing the wavelength conversion) in the planar direction is a member that is perpendicular to the planar direction, by attaching the optical component having a triangular prism shape (its two surfaces on the end face 93-side and on the first solar cell 103-side being perpendicular to each other, and its oblique end face-side surface having a planar shape) 99 on this end face 93, the wavelength conversion optical plate 101 with its end face 97 being oblique is easily produced.

It is desirable that this optical component 99 to be attached have capability for wavelength conversion, but this capability may be unnecessary.

### Ninth Embodiment

A ninth embodiment of the invention will be described. Description similar to the first embodiment is omitted. As illustrated in FIG. 6B, a solar cell module 111 of the present embodiment is obtained as a result of attaching a solar cell 117 which is an Si single crystal, for example, on one surface of a wavelength conversion optical plate 115 having the inclined end face 113 in its thickness direction.

Particularly, in the present embodiment, the wavelength conversion optical plate 115 is obtained as a result of bonding together a blue conversion optical plate 119 that converts ultraviolet rays into blue (400 nm≦wavelength≦500 nm), a green conversion optical plate 121 that converts ultraviolet rays into green (500 nm≦wavelength≦600 nm), and a red conversion optical plate 123 that converts ultraviolet rays into red (600 nm≦wavelength≦700 nm) from a light incident side (upper side in FIG. 6B) one after another by an optical silicon resin adhesive.

The blue conversion optical plate 119 is an Eu²⁺ added blue conversion optical plate (P₂O₃, AlF₃, MgF₂, CaF₂, SrF₂, BaCl₂: Eu²⁺) with a size of 96 mm longitudinally, 96 mm laterally, and 1 mm in thickness having an oblique end face for its outer circumference. The green conversion optical plate 121 is an Eu³⁺ added green conversion optical plate (SiO₂, B₂O₃, BaO, ZnO: Eu³⁺) with a size of 98 mm longitudinally, 98 mm laterally, and 1 mm in thickness having an oblique end face for its outer circumference. The red conversion optical plate 123 is a Tb³⁺ added red conversion optical plate (B₂O₃, CaO, SiO₂, LaO₃: Tb³⁺) with a size of 100 mm longitudinally and 100 mm laterally and 1 mm in thickness having an oblique end face for its outer circumference.

In the present embodiment, the wavelength conversion optical plates 119 to 123, which convert most efficiently solar light and light of each wavelength that has been converted, are stacked up. Accordingly, the photoelectric conversion efficiency improves as a whole. Generally, a wavelength conversion optical plate that produces luminescence (fluorescence) with blue absorbs an ultraviolet light; a wavelength conversion optical plate that produces luminescence with green absorbs lights up to blue; sand a wavelength conversion optical plate that produces luminescence with red absorbs lights up to green. Accordingly the light that is emitted at the wavelength conversion optical plate on the incident side is absorbed and becomes luminous in the wavelength conversion optical plate of the lower layer (on the emission side). As a result, absorption wavelength and emission wavelength are separated, so that a loss is reduced. Thus, the photoelectric conversion efficiency as a whole improves.

### Tenth Embodiment

A tenth embodiment of the invention will be described. Description similar to the first embodiment is omitted. As illustrated in FIG. 6C, a solar cell module 131 of the present embodiment is obtained as a result of attaching a solar cell 137 which is an Si single crystal, for example, on one surface of a wavelength conversion optical plate 135 having a generally inclined end face 133 in its thickness direction.

The wavelength conversion optical plate 135 is obtained, similar to the ninth embodiment, as a result of bonding together a blue conversion optical plate 139, a green conversion optical plate 141, and a red conversion optical plate 143 from the light incident side (upper side in FIG. 6C) by an optical silicon resin adhesive respectively via optical plates 145, 147 without a wavelength conversion function having a thickness of 1 μm to 1 mm and made of transparent glass or resin. In addition, a similar optical plate 149 is disposed also between the red conversion optical plate 143 and the solar cell 137.

In the present embodiment, effects similar to the ninth embodiment are produced, and the optical plates 145 to 149 having different refractive indexes from the conversion optical plates 139 to 143 are arranged between the conversion optical plates 139 to 143 and so forth. Accordingly, the light, which has entered, is multiply-reflected in the respective conversion optical plates 139 to 149. The light is concentrated and reflected more efficiently on the end face 133, and finally, the light enters into the solar cell 137. Thus, the photoelectric conversion efficiency improves.

By simply providing spaces instead of the transparent optical plates 145 to 149, similar effects are produced.

### Eleventh Embodiment

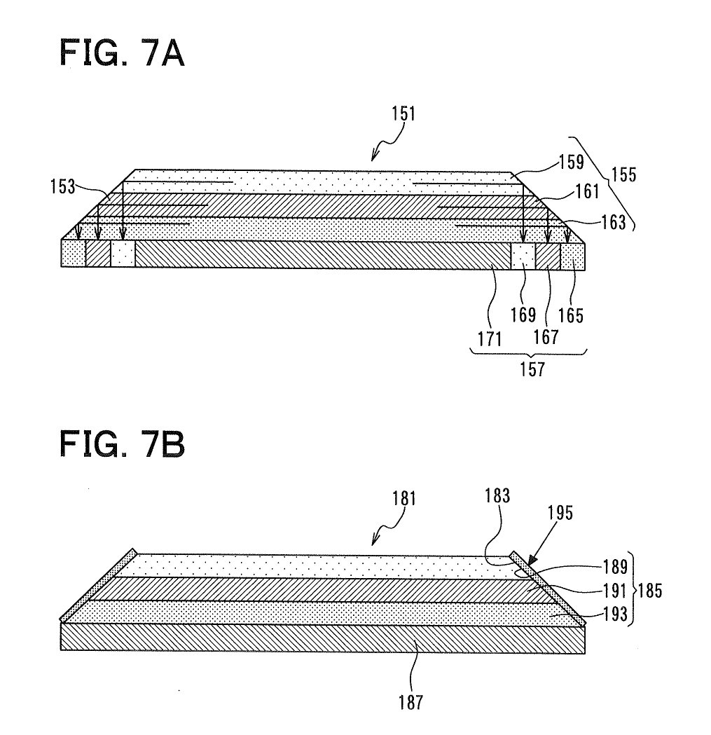

An eleventh embodiment of the invention will be described. Description similar to the ninth embodiment is omitted. As illustrated in FIG. 7A, a solar cell module 151 of the present embodiment is obtained as a result of attaching a solar cell 157, on one surface of a wavelength conversion optical plate 155 having the inclined end face 153 in its thickness direction.

In the solar cell module 151, the wavelength conversion optical plate 155 is obtained, similar to the ninth embodiment, as a result of bonding together a blue conversion optical plate 159, a green conversion optical plate 161, and a red conversion optical plate 163 from the light incident side (upper side in FIG. 7A) by an optical silicon resin adhesive.

Particularly, in the present embodiment, a Ge (Eg: 0.7 eV) solar cell 165 with a width of 1 mm having a quadrilateral frame shape is attached on the outermost periphery of an emission side-lower surface of the wavelength conversion optical plate 155; a GaAs (Eg: 1.4 eV) solar cell 167 with a width of 1 mm having a quadrilateral frame shape is attached inward of the Ge solar cell 165; an InGaP (Eg: 1.9 eV) solar cell 169 with a width of 1 mm having a quadrilateral frame shape is attached inward of the GaAs solar cell 167; and a square Si (Eg: 1.1 eV) solar cell 171 is attached inward of the InGaP solar cell 169.

Accordingly, at positions that the lights, whose wavelengths are converted in the respective conversion optical plates 159 to 163 and which are reflected on the corresponding end faces (end faces inclined by 45 degrees), can most easily enter into, i.e., at positions below the respective end faces in FIG. 7A, the solar cells 165 to 169 which are the most sensitive to the corresponding wavelength-converted lights are located.

If the wavelength conversion optical plates that convert the wavelength into blue, green, and red from the incident side are stacked, for example, from the outer side in the planar direction in accordance with the reflecting direction of each wavelength conversion optical plate, the respective solar cells having high conversion efficiency for red, green, blue are arranged in order, to receive lights of red, green, and blue correspondingly more than the other lights.

As a result, photoelectric conversion efficiency of the entire solar cell module 151 is improved at low cost.

### Twelfth Embodiment

A twelfth embodiment of the invention will be described. Description similar to the ninth embodiment is omitted. As illustrated in FIG. 7B, a solar cell module 181 of the present embodiment is obtained as a result of attaching a solar cell 187 which is an Si single crystal, for example, on one surface of a wavelength conversion optical plate 185 having the inclined end face 183 in its thickness direction.

In the solar cell module 181, the wavelength conversion optical plate 185 is obtained, similar to the ninth embodiment, as a result of bonding together a blue conversion optical plate 189, a green conversion optical plate 191, and a red conversion optical plate 193 from the light incident side (upper side in FIG. 7B) by an optical silicon resin adhesive.

Particularly, in the present embodiment, for example, a reflective film 195 which is made of aluminium and is a thin film that reflects light, is formed such as by evaporation coating or sputtering on an outer surface of the slanted end face 183 of the wavelength conversion optical plate 185.

Accordingly, in the present embodiment, the light, whose wavelength has been converted in the wavelength conversion optical plate 185 and which has reached the slanted end face 183, is reflected approximately 100% on the end face 195. The light enters efficiently into the solar cell 187.

Embodiments of a solar panel of the invention will be described below by giving some specific examples.

### Thirteenth Embodiment

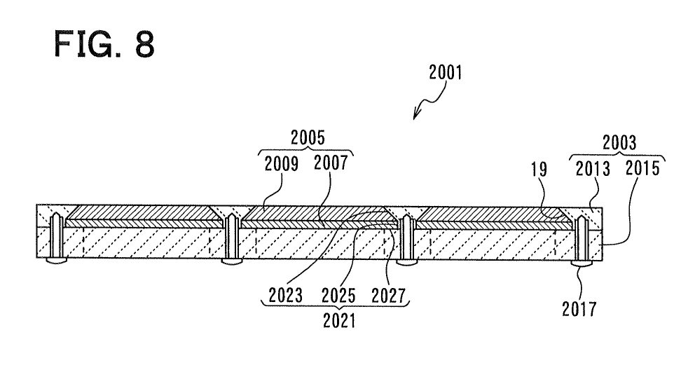

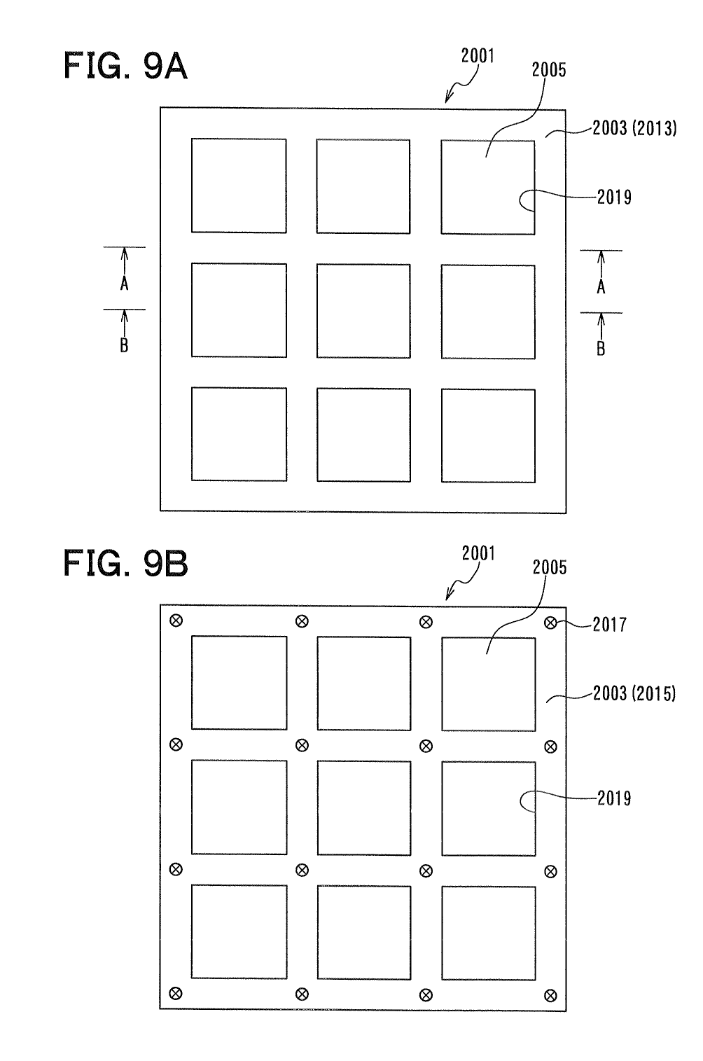

A configuration of a solar panel of the present embodiment will be described. As illustrated in FIGS. 8 to 9B, a solar panel 2001 of the present embodiment is a plate-like member obtained as a result of arranging and fixing more than one (e.g., nine) plate-like solar cell module 2005 in a planar direction, to a lattice-shaped frame 2003 made of resin (made of acid-breakable (AB) resin for example).

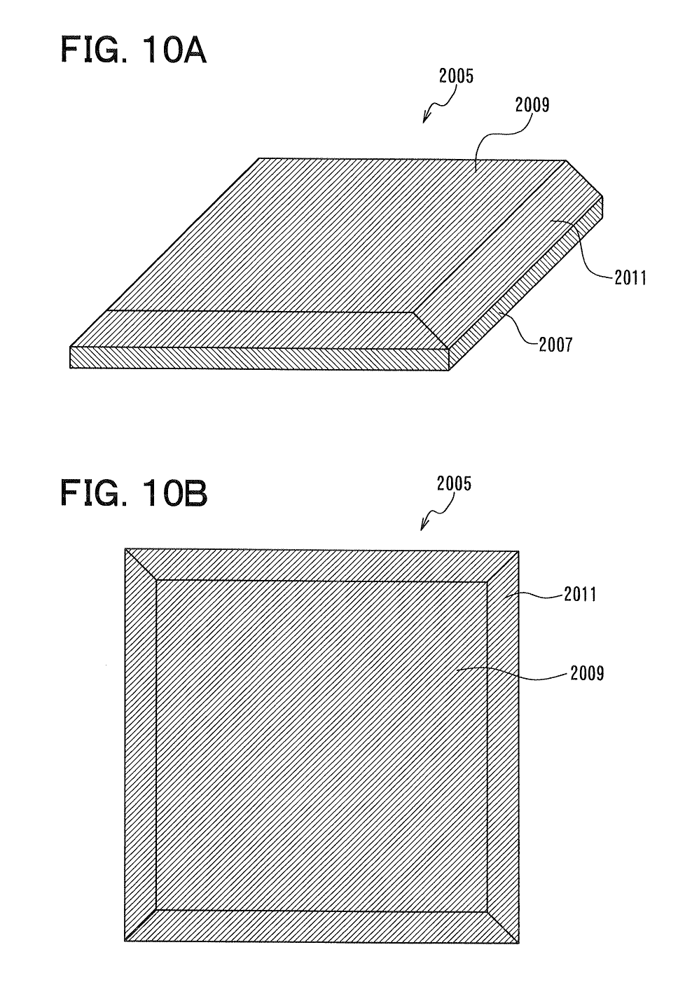

As illustrated in FIGS. 10A and 10B, the solar cell module 2005 is obtained as a result of bonding a solar cell 2007 on one side (lower side in FIG. 10A) of a wavelength conversion optical plate 2009 in its thickness direction by an optical adhesive having translucency (e.g., optical silicon resin adhesive) A flat surface shape of the plate 2009 is a square. Similarly, a flat surface shape of the cell 2007 is square.

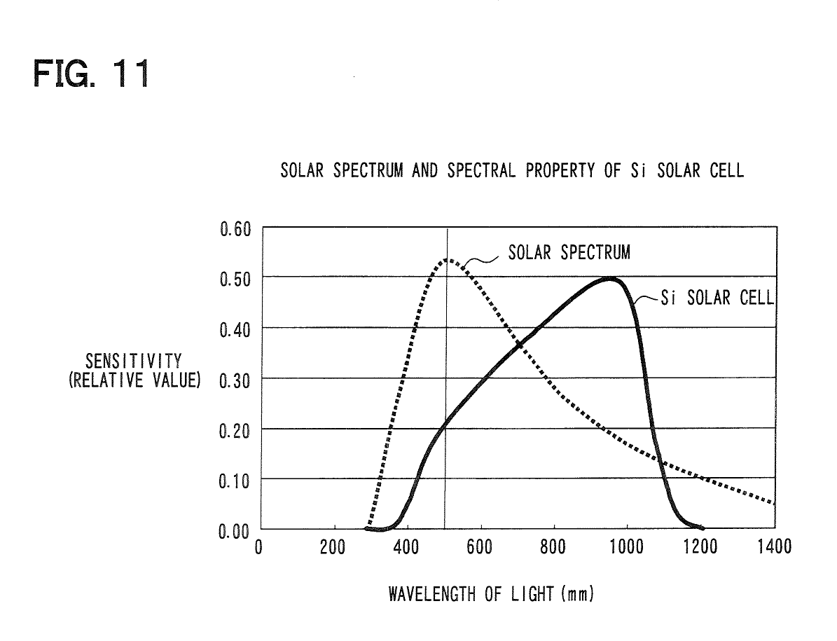

The solar cell 2007 is an Si single crystal cell having a size of 100 mm longitudinally, 100 mm laterally, and 200 nm in thickness. The cell 2007 has a spectral characteristic (spectral sensitivity characteristic) illustrated FIG. 11. As illustrated in FIG. 11, this second solar cell 2007 hardly generates electricity in an ultraviolet light area that is equal to or smaller than 400 nm. In FIG. 11, the spectral sensitivity characteristic is schematically indicated by a continuous line, and energy distribution of the solar light is schematically indicated by a short dashes line.

The wavelength conversion optical plate 2009 is a transparent hard flat plate having a size of 100 mm longitudinally, 100 mm laterally, and 3 mm in thickness. End faces (four sides) 2011 of the plate 2009 along its whole circumference in the planar direction (direction perpendicular to the thickness direction) are cut obliquely relative to the planar direction (inclined by 45 degrees, for example) to be broader on the solar cell 2007-side.

The wavelength conversion optical plate 2009 is made of LUMILAS G9 (trade name), for example, and constituted of fluorescent glass (B₂O₃.CaO.SiO₂.La₂O₃.Tb³⁺) with Tb added. This wavelength conversion optical plate 2009 absorbs light in an ultraviolet region that is equal to or smaller than the wavelength 400 nm of light, and shows fluorescence at a wavelength of 545 nm.

As illustrated in FIGS. 8 to 9B, the frame 2003 is a member (whose flat surface shape is a square) spreading in a grid-like manner on the same flat surface. The frame 2003 is composed of an upper frame 2013 and a lower frame 2015 between which the solar cell module 2005 is disposed from upper and lower directions in FIG. 8. The upper frame 2013 and the lower frame 2015 are fixed together by a screw 2017.

In the invention, the frame includes the upper frame and lower frame. Accordingly, by clamping the solar cell module by both the frames, the solar cell module is easily and reliably fixable.

An accommodating part 2019 (whose flat surface shape is a square) that opens at nine sections is provided for the frame 2003, to arrange and accommodate the nine solar cell modules 2005 in a reticular pattern such that the planar direction of the solar cell modules 2005 themselves and a planar direction of the solar panel 2001 coincide with each other.

As illustrated in FIG. 8, a fixing part 2021 for fixing an end portion of the solar cell module 2005 in the planar direction is provided for an inner circumferential portion of the frame 2003 facing the accommodating part 2019. More specifically, on an inner circumferential portion of the upper frame 2013 facing the accommodating part 2019, a fixing part side end face 2023, which is inclined at the same angle as the oblique end face 2011 to be in contact with the end face 2011 of the wavelength conversion optical plate 2009 in the planar direction along its whole surface, is formed; and a fixing part side vertical surface 2025, which extends from the fixing part side end face 2023 toward the lower frame 2015, is formed. A fixing part side upper surface 2027 is formed on an inner circumferential portion of the lower frame 2015 facing the accommodating part 2019 (upper surface of the frame 2015), to be in contact with a peripheral part of a lower surface of the solar cell 2007 (reverse face on the opposite side of the light entering side).

Accordingly, when the solar cell module 2005 is placed between the upper frame 2013 and the lower frame 2015 in the accommodating part 2019, the end portion of the solar cell module 2005 is fixed to the fixing part 2021.

In the invention, the fixing part of the frame is engaged with the slanted end face of the wavelength conversion optical plate and with the opposite side (reverse side) from the light entering side of the solar cell, i.e., the fixing part clamps the solar cell module from both sides in the thickness direction. Accordingly, the solar cell module is easily and reliably fixable to the frame.

Functions of the solar panel 2001 of the present embodiment will be described. A part of solar light which has entered into the solar cell module 2005 from the outside generates a fluorescence of 545 nm in the wavelength conversion optical plate 2009. The light (fluorescence) reflects and is concentrated in the wavelength conversion optical plate 2009. The light enters into and reflects on the inclined end face 2011 of the wavelength conversion optical plate 2009 that is inclined by 45 degrees, and the light enters into the solar cell 2007 through a reverse face of the wavelength conversion optical plate 2009 (on the opposite side of the incident side).

At the same time, incident light (light which is not fluorescence) under the total reflection condition, which enters into the solar cell module 2005 from the outside, reflects similarly on the end face 2011 and enters into the first solar cell 2007. Because of these effects, the photoelectric conversion amount of this portion improves.

The fluorescence of 545 nm is generated in the wavelength conversion optical plate 2009. The light of this fluorescence of 545 nm which does not enter into the end face 2011 enters into the second solar cell 2007. Accordingly, the amount of, photoelectric conversion improves slightly. Furthermore since glass which constitutes this wavelength conversion optical plate 2009 is transparent, most of the lights from visible light to infrared light permeate the wavelength conversion optical plate 2009 and enter into the second solar cell 2007 to be photoelectrically converted.

A method for making the solar panel 2001 of the present embodiment will be briefly described. For example, the upper frame 2013 is placed upside down (e.g., FIG. 8 is turned upside down). Therefore, the upper frame 2013 is placed with a large opening of the accommodating part 2019 directed upward.

The solar cell module 2005 is housed in this opened accommodating part 2019 with the wavelength conversion optical plate 2007-side directed downward. Accordingly, the inclined end face 2011 of the wavelength conversion optical plate 2007 and the fixing part side end face 2023 are brought into contact.

Then, positions of the upper frame 2013 and the lower frame 2015 are aligned, and they are fixed together by the screw 2017. Accordingly, the solar cell module 2005 is fixed in the accommodating part 2019 of the frame 2003.

In the present embodiment, the inclined end face 2011 is formed on the wavelength conversion optical plate 2009. Accordingly, the light, which has been wavelength-converted and concentrated in the wavelength conversion optical plate 2009, reflects appropriately on the plate end face toward the solar cell 2007, and enters into the solar cell 2007. As a result, the photoelectric conversion efficiency improves in the entire solar cell module 2005, eventually, in the entire solar panel 2001.

Moreover, in the present embodiment the solar cell module 2005, which is obtained by attaching the solar cell 2007 on the hard wavelength conversion optical plate 2009 made of glass and having a thickness of 3 mm, is arranged and fixed in the frame 2003. Unlike a solar panel, on which a conventional solar cell that is a thin film is attached, the optical plate 2009 is not easily broken or bent. More specifically, the solar cell module 2005 is disposed between the upper and lower frames 2013, 2015, and the end portion of the module 2005 in the planar direction is fixed to the fixing part 2021. Accordingly, the solar panel 2001 is easily produced at low cost.

Even more specifically, the plate-like solar cell modules are arranged (with the planar directions of the solar cell modules themselves in accord with each other) along the planar direction of the solar panel, and the end portion of each solar cell module in its planar direction is fixed to the fixing part of the frame. Accordingly, the solar panel is easily produced at low cost.

Particularly, the slanted end face 2011 of the wavelength conversion optical plate 2009, and the oblique end face of the fixing part 2021 (fixing part side end face 2023) are in contact on their whole surfaces. Accordingly, the solar cell module 2005 is easily and reliably fixed.

### Fourteenth Embodiment

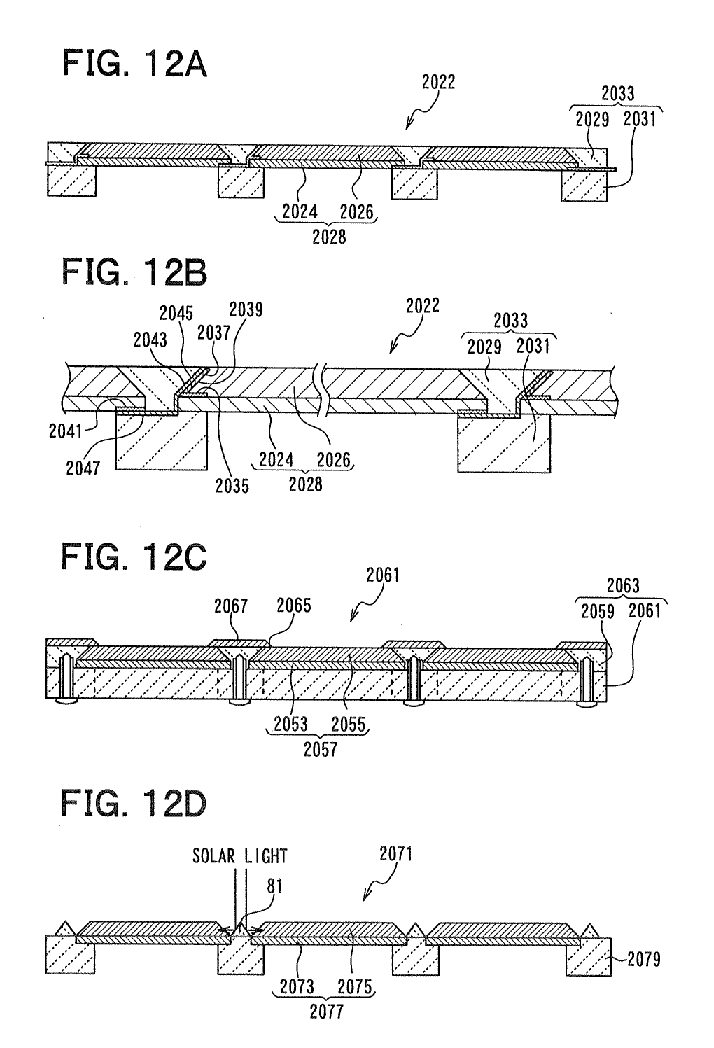

A fourteenth embodiment of the invention will be described Description similar to the thirteenth embodiment is omitted. As illustrated in FIG. 12A and FIG. 12B which enlarges its main feature, similar to the thirteenth embodiment, a solar panel 2022 of the present embodiment is obtained as a result of clamping and fixing a solar cell module 2028 including a solar cell 2024 and a wavelength conversion optical plate 2026 by a frame 2033, which is constituted of an upper frame 2029 and a lower frame 2031.

Particularly, in the present embodiment, a conductive layer 2039 is formed on, an inclined end face 2037 of the wavelength conversion optical plate 2026 in the planar direction, to be electrically connected to an upper electrode 2035 which is provided on one side (upper side in FIG. 12B) of the solar cell 2024 in its thickness direction. The other electrode (lower electrode 2041) of the solar cell 2024 is provided on a surface of the solar cell 2024 on the opposite side (lower side in FIG. 12B) from the upper electrode 2035.

An upper frame conductive layer 2045 is provided for the upper frame 2029, on an inclined fixing part side end face 2043 of the upper frame 2029 to be in contact with the conductive layer 2039 on the inclined end face 2037 of the wavelength conversion optical plate 2026. This upper frame conductive layer 2045 is extended to reach the lower frame 2031.

A lower frame conductive layer 2047 is formed on an upper surface of the lower frame 2031 to be in contact with the adjacent other lower electrode 2041 of the solar cell 2024. This lower frame conductive layer 2047 is extended in the planar direction (rightward in FIG. 12B) to be electrically connected to a lower end of the upper frame conductive layer 2045.

Accordingly, in the present embodiment, when the solar cell modules 2028 are fixed between the upper frame 2029 and the lower frame 2031, the solar cells 2024 are automatically connected in series. As a result, the assembly production is simplified, and a prominent effect of contributing to cost reduction is produced.

In the invention, a wiring is provided for the frame (particularly, for the fixing part). Accordingly, when the solar cell module is fixed to the frame, an electric connection between the electrode of the solar cell and the wiring of the frame is easily made.

As a result, in the case in which the solar cells are connected in series, for example, by only fixing the solar cell module to the fixing part, connection of the solar cells is made via the wiring provided on the fixing part. Thus, assembly production is simplified to contribute to cost reduction.

Preferably, the electrode of the solar cell may be formed longer than a conventional electrode (e.g., to be exposed to the end portion (end face) of the wavelength conversion optical plate in its planar direction), to be connectable to the wiring of the frame, i.e., such that the electrode of the solar cell and the wiring of the frame are in contact when the solar cell module is fixed to the frame.

### Fifteenth Embodiment

A fifteenth embodiment of the invention will be described. Description similar to the thirteenth embodiment is omitted. As illustrated in FIG. 12C, similar to the thirteenth embodiment, a solar panel 2061 of the present embodiment is obtained as a result of clamping and fixing a solar cell module 2057 including a solar cell 2053 and a wavelength conversion optical plate 2055 by a frame 2063, which is constituted of an upper frame 2059 and a lower frame 2061.

Particularly, in the present embodiment, an auxiliary wavelength conversion optical plate 2067 having a slanted (in the planar direction) end face 2065, which is similar to the wavelength conversion optical plate 2055, is attached on an upper surface side (solar light incident side) of the upper frame 2059.

A lower surface (surface on a lower side of the oblique end face 2065) of an end portion of this auxiliary wavelength conversion optical plate 2067 in right and left directions in FIG. 12C is disposed to cover the end portion of the upper surface of the wavelength conversion optical plate 2055. Accordingly, in the present embodiment, the solar light, which has entered toward the upper frame 2059, is wavelength-converted and concentrated in the auxiliary wavelength conversion optical plate 2067, and the solar light is introduced into the wavelength conversion optical plate 2055. As a result, the solar light is used effectively with economy. Therefore, the loss at the time of using the solar light is lessened.

### Sixteenth Embodiment

A sixteenth embodiment of the invention will be described. Description similar to the thirteenth embodiment is omitted. As illustrated in FIG. 12D, a solar panel 2071 of the present embodiment is obtained as a result of fixing a solar cell module 2077 made up of a solar cell 2073 and a wavelength conversion optical plate 2075, which is similar to the thirteenth embodiment, to a lower frame 2079 by an optical adhesive, for example.

Particularly, in the present embodiment, a triangular prism-shaped reflective member 2081 is fixed on a surface of the lower frame 2079 which is exposed between the adjacent solar cell modules 2077, by an adhesive, for example. This reflective member 2081 is obtained as a result of forming a reflective film (aluminum as a result of mirror) by evaporating and sputtering aluminium on a surface of a resin member, for example. The reflective member 2081 is a member whose cross section perpendicular to its axial direction is a triangle (e.g., equilateral triangle).

Accordingly, in the present embodiment, the solar light, which has entered between the solar cell modules 2077, reflects on the slant face of the reflective member 2081, to enter toward the end portion of the wavelength conversion optical plate 2071 in its planar direction. As a result, the solar light is used effectively with economy. Therefore the loss at the time of using the solar light is lessened.

### Seventeenth Embodiment

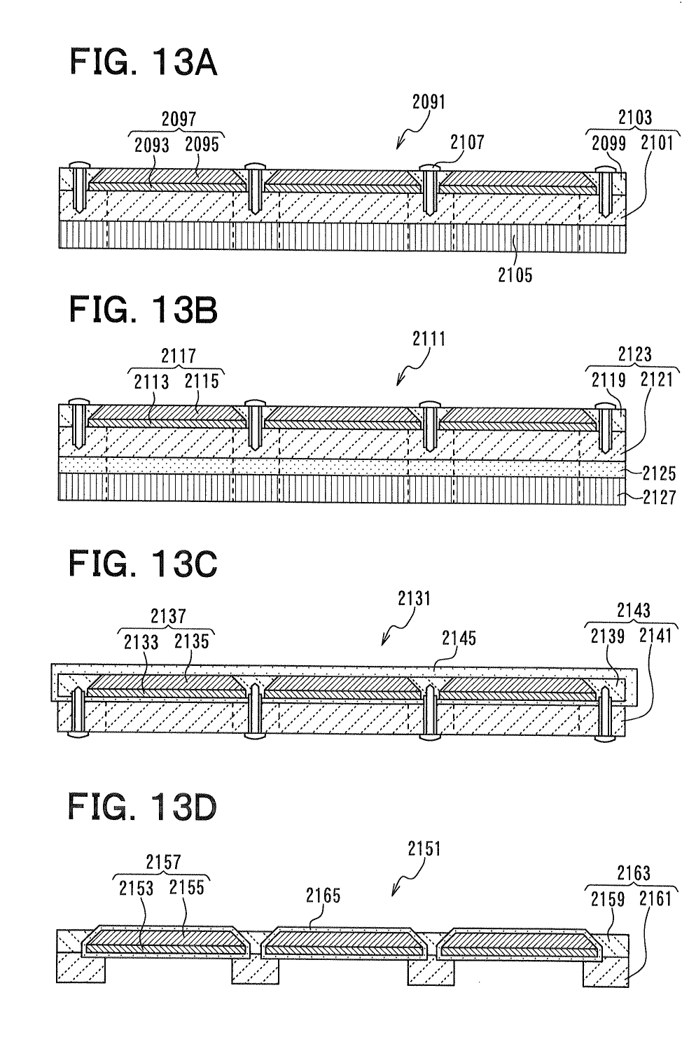

A seventeenth embodiment of the invention will be described. Description similar to the thirteenth embodiment is omitted. As illustrated in FIG. 13A, similar to the thirteenth embodiment, a solar panel 2091 of the present embodiment is obtained as a result of clamping and fixing a solar cell module 2097 including a solar cell 2093 and a wavelength conversion optical plate 2095 by a frame 2103, which is constituted of an upper frame 2099 and a lower frame 2101.

Particularly, in the present embodiment, fins (radiation fins) 2105 for cooling are attached and fixed on a lower surface side of the lower frame 2101, by an adhesive, for example. Accordingly, an effect of limiting efficiency deterioration due to the heat from the solar cell 2093 is produced.

In the present embodiment, the upper frame 2099 and the lower frame 2101 are fixed together by a screw 2107 that is screwed from the upper frame 2099-side.

### Eighteenth Embodiment

An eighteenth embodiment of the invention will be described. Description similar to the seventeenth embodiment is omitted. As illustrated in FIG. 13B, similar to the seventeenth embodiment, a solar panel 2111 of the present embodiment is obtained as a result of clamping and fixing a solar cell module 2117 including a solar cell 2113 and a wavelength conversion optical plate 2115 by a frame 2123, which is constituted of an upper frame 2119 and a lower frame 2121.

Particularly, in the present embodiment, the solar panel 2111 includes a thermoelectric element 2125 made of such as bismuth telluride (BiTe) and attached by an adhesive, for example, on a lower surface side of the lower frame 2121; and the solar panel 2111 further includes fins (radiation fins) 2127 for cooling attached by an adhesive, for example, on a lower surface side of the thermoelectric element 2125.

Accordingly, the effect in the seventeenth embodiment is produced and electricity is generated using the heat as well. As a result, energy of the solar light is utilized even more effectively.

### Nineteenth Embodiment

A nineteenth embodiment of the invention will be described. Description similar to the thirteenth embodiment is omitted. As illustrated in FIG. 13C, similar to the thirteenth embodiment, a solar panel 2131 of the present embodiment is obtained as a result of clamping and fixing a solar cell module 2137 including a solar cell 2133 and a wavelength conversion optical plate 2135 by a frame 2143, which is constituted of an upper frame 2139 and a lower frame 2141.

Particularly, in the present embodiment, the solar cell module 2137 and the upper frame 2139 are covered with a translucent resin sheet (or resin plate) 2145 made of vinyl chloride, for example; and the lower frame 2141 is fixed to the upper frame 2139 from their outer side (lower side in FIG. 13C).

Accordingly, influence of humidity is inhibited and dirt, such as dust, is prevented.

### Twentieth Embodiment

A twentieth embodiment of the invention will be described. Description similar to the thirteenth embodiment is omitted. As illustrated in FIG. 13D, similar to the thirteenth embodiment, a solar panel 2151 of the present embodiment is obtained as a result of clamping and fixing a solar cell module 2157 including a solar cell 2153 and a wavelength conversion optical plate 2155 by a frame 2163, which is constituted of an upper frame 2159 and a lower frame 2161.

Particularly, in the present embodiment, each solar cell module 2157 is covered with a resin sheet (or resin plate) 2165 made of vinyl chloride, for example, and they are fixed by the lower frame 2159 and the upper frame 2161.

Accordingly, influence of humidity is inhibited and dirt, such as dust, is prevented.

Embodiments of a solar cell module of the invention will be described below by giving some specific examples.

### Twenty-First Embodiment

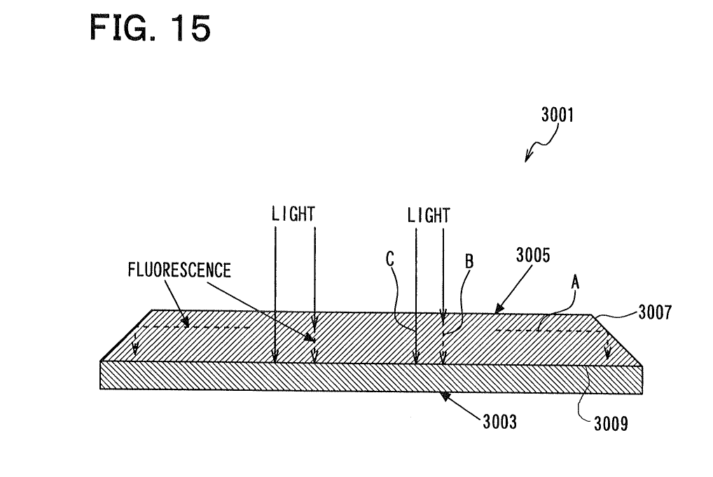

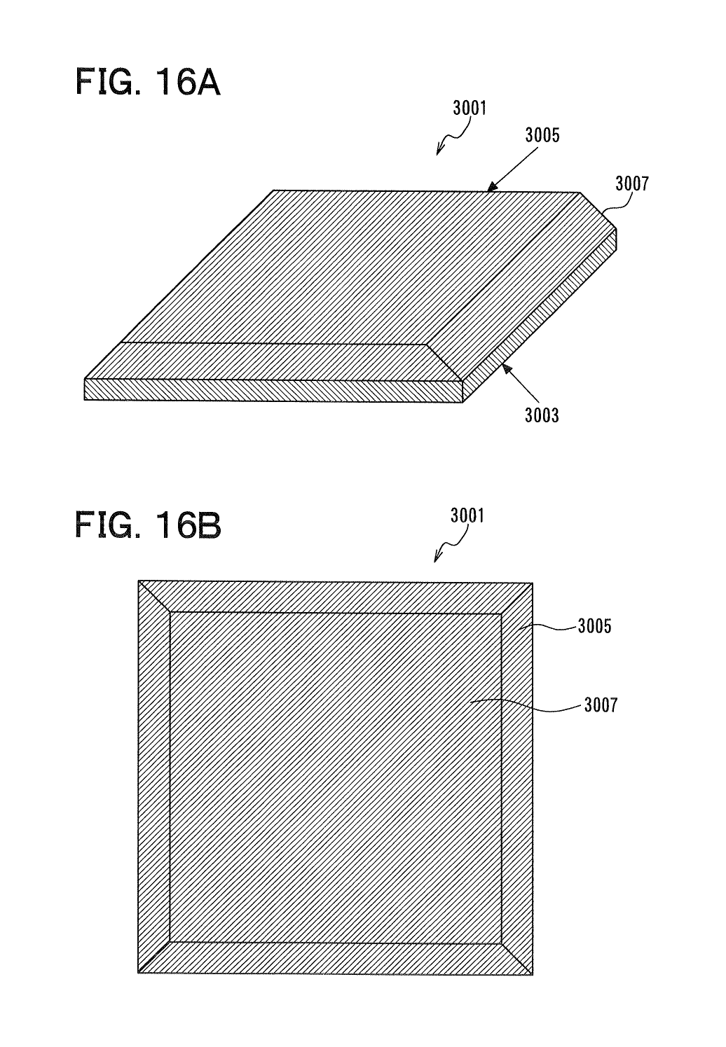

A configuration of a solar cell module of the present embodiment will be described. As illustrated in FIGS. 15 to 16B, a solar cell module 3001 of the present embodiment is obtained as a result of bonding a solar cell 3003 on one side (lower side in FIG. 15) of a wavelength conversion optical plate 3005 in its thickness direction by an optical adhesive having translucency (e.g., optical silicon resin adhesive). A flat surface shape of the plate 3005 is a square. Similarly, flat surface shape of the cell 3003 is square.

The solar cell 3003 is an Si single crystal cell having a size of 100 mm longitudinally, 100 mm laterally, and 200 nm in thickness. The cell 3003 has a spectral characteristic (spectral sensitivity characteristic) illustrated FIG. 11. As illustrated in FIG. 11 this solar cell 3003 hardly generates electricity in an ultraviolet light area that is equal to or smaller than 400 nm. In FIG. 11, the spectral sensitivity characteristic is schematically indicated by a continuous line, and energy distribution of the solar light is schematically indicated by a short dashes line.

Particularly, in the present embodiment the wavelength conversion optical plate 3005 is a transparent flat plate having a size of 100 mm longitudinally, 100 mm laterally, and 3 mm in thickness. End faces (four sides) 3007 of the plate 3005 along its whole circumference in the planar direction (direction perpendicular to the thickness direction) are cut obliquely relative to the planar direction (inclined by 45 degrees, for example) to be broader on the solar cell 3003-side.

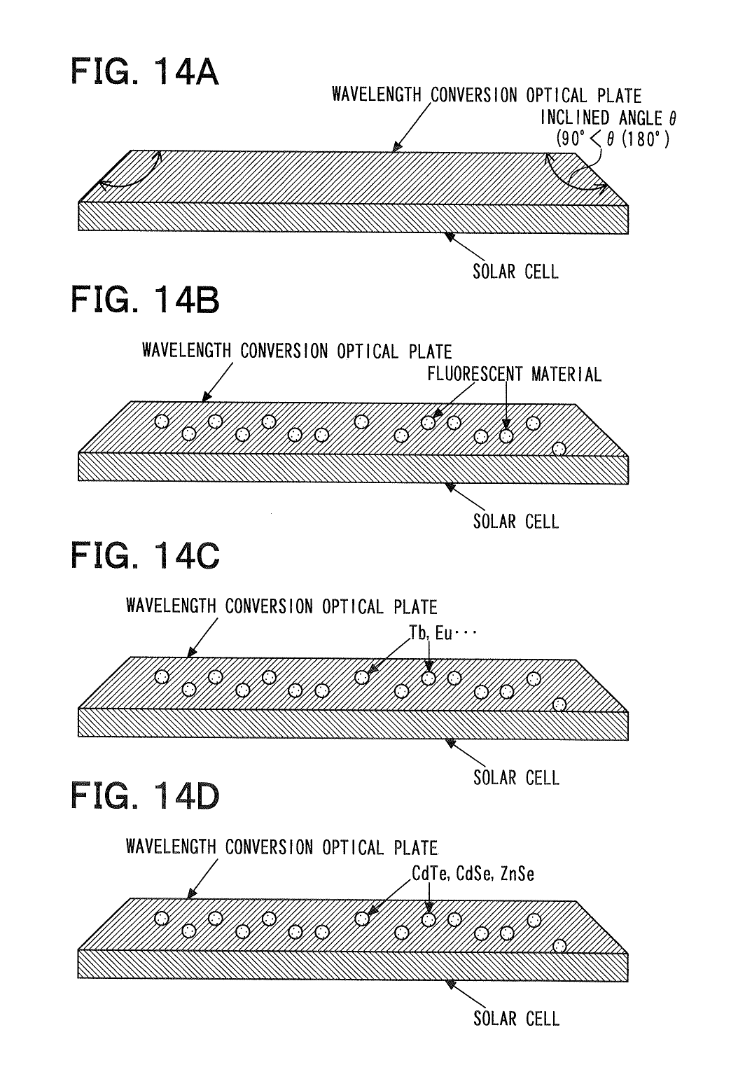

The wavelength conversion optical plate 3005 is made of LUMILAS G9 (trade name), for example, and constituted of fluorescent glass (B₂O₃.CaO.SiO₂.La₂O₃.Tb³⁺) with terbium (Tb) added (see FIG. 14C). This wavelength conversion optical plate 3005 absorbs light in an ultraviolet region that is equal to or smaller than the wavelength 400 nm of light, and shows fluorescence at a wavelength of 545 nm.

Functions of the solar cell module 3001 of the present embodiment will be described. In the present embodiment, as illustrated, in FIG. 15, a part of solar light which has entered into the solar cell module 3001 from the outside generates a fluorescence of 545 nm in the wavelength conversion optical plate 3005. The light (fluorescence) reflects and is concentrated in the wavelength conversion optical plate 3005. The light enters into and reflects on the inclined end face 3007 of the wavelength conversion optical plate 3005 that is inclined by 45 degrees (short dashes line A), and the light enters into the solar cell 3003 through a lower surface 3009 of the wavelength conversion optical plate 3005. At the same time, incident light (light which is not fluorescence) under the total reflection condition, which enters into the solar cell module 3001 from the outside, reflects similarly on the end face 3007 and enters into the first solar cell 3003. Because of these effects, the photoelectric conversion amount of this portion improves.

The fluorescence of 545 nm is generated in the wavelength conversion optical plate 3005. The light (short dashes line B) of this fluorescence of 545 nm which does not enter into the end face 3007 enters into the solar cell 3003. Accordingly, the amount of photoelectric conversion improves slightly. Furthermore, since glass which constitutes this wavelength conversion optical plate 3005 is transparent, most of the lights from visible light to infrared light permeate (continuous C) the wavelength conversion optical plate 3005 and enter into the solar cell 3003 to be photoelectrically converted.

Accordingly, in the present embodiment as a result of the combination of these three photoelectric conversions, the conversion efficiency of the solar cell 3003 improves to 21%, whereas conversion efficiency is 17.5% for the solar cell 3003 alone. In the case of production of the solar cell module 3001 of the present embodiment, the wavelength conversion optical plate 3005 with its end face 3007 obliquely cut only needs to be attached on the solar cell 3003 in the thickness direction of the solar cell 3003. Accordingly, compared to the conventional technology, the production is very simple, and a special jig or the like is not needed. As a result, there is an advantage of low costs.

For example, as illustrated in FIG. 11, if the solar cell is an Si solar cell, the lights from ultraviolet to blue (300 nm to 500 nm) have low spectral sensitivity. Accordingly, a wavelength in this region is converted into a wavelength that is equal to or larger than 500 nm having high spectral sensitivity in the wavelength conversion optical plate including fluorochrome, for example. The converted and concentrated light is reflected on the inclined end portion (end face) of the wavelength conversion optical plate and the reflected light enters into the Si solar cell located in the thickness direction (e.g., lower part) of the wavelength conversion optical plate. At the same time, the light, which has entered from the outside through the surface of the wavelength conversion optical plate in its thickness direction, is hardly absorbed in the wavelength conversion optical plate at a wavelength that is equal to or larger than blue (500 nm). The light permeates the optical plate to enter into the Si solar cell. Furthermore, the lights from ultraviolet to blue (300 nm to 500 nm) are converted into a light having a wavelength that is equal to or larger than blue (500 nm) in the wavelength conversion optical plate, and the light enters into the Si solar cell. The generation efficiency of the solar cell module is improved through the combination of these three effects.

Moreover, in the invention, by only attaching, for example, a normal Si solar cell on the wavelength conversion optical plate (using such as an optical adhesive) in the thickness direction of the optical plate, the effect of improving the generation efficiency is produced. Accordingly, the solar cell module is easily produced, and its production costs can also be reduced.

For example, thin film Si, copper indium gallium diSelenide (CIGS), cadmium telluride (CdTe), GaAs, dye-sensitised type, organic dye type, and so forth, may be used for the solar cell. A range of 125°<θ<145° may be even more appropriate as the inclined angle θ.

The following configurations may be employed for modifications of the present embodiment. The end face 3007 may be obliquely cut after the solar cell 3003 is attached on the wavelength conversion optical plate 3005.

Also, as is normally done, a method of cutting a plate material by such as a cutter, or a method of forming through surface polish, for example, may be employed for the method of cutting slantwise the wavelength conversion optical plate 3005. Or, when forming the wavelength conversion optical plate 3005 made of glass, the wavelength conversion optical plate 3005 may be formed within a mold of a target shape.

As illustrated in FIG. 14D, various kinds of fluorescent materials such as a semiconductor nano fluorescent material may be used for the fluorescent material.

As illustrated in FIG. 14D, for example, the invention illustrates the fluorescent material. For example, a particle having a size of a particle diameter of 1 nm to 8 nm may be employed for the semiconductor nano fluorescent material (nanosized particle).

In the invention, the band gap is widened because of the quantum size effect. The ultraviolet light is absorbed suitably, and high-intensity visible light is emitted.

### Twenty-Second Embodiment

A twenty-second embodiment of the invention will be described.

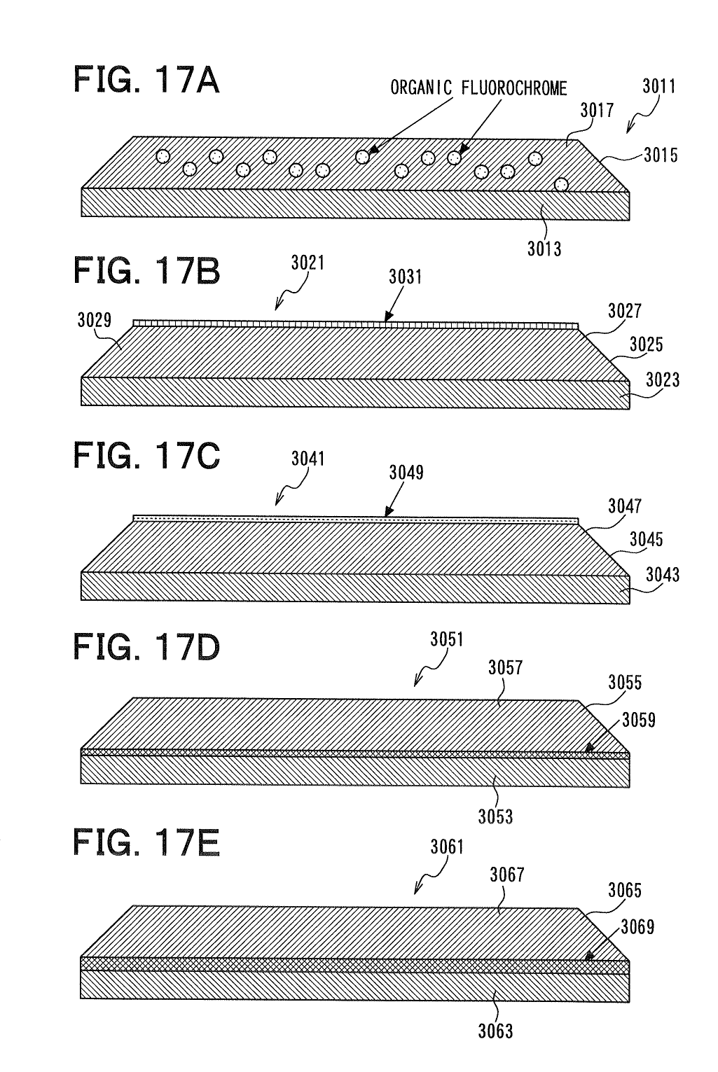

Description similar to the twenty-first embodiment is omitted. As illustrated in FIG. 17A, similar to the twenty-first embodiment, a solar cell module 3011 of the present embodiment is obtained as a result of attaching a solar cell 3013 on a wavelength conversion optical plate 3017 in a thickness direction of the plate 3017 with its end face 3015 obliquely cut.

The wavelength conversion optical plate 3017 of the present embodiment is obtained as a result of mixing an organic fluorescent material (organic fluorochrome) made of Lumogen (trade name: produced by BASF Co.), for example, in transparent resin made of acrylic (poly methyl methacrylate: PMMA), for example.

In the invention, as illustrated in FIG. 14B, a fluorescent material (fluorochrome) is mixed in transparent glass or resin as an impure substance. Accordingly, when the light which has entered into the wavelength conversion optical plate reaches the fluorescent material, a fluorescence having a wavelength (e.g., 500 nm to 800 nm) that is appropriate for electricity generation is generated. Therefore, generation efficiency can be improved.

Transparent and colorless glass and resin are the most desirable, but, they may be colored. For example, silica, boron oxide glass may be used for the glass, and for example, acrylic or polycarbonate may be used for the resin.

The invention illustrates the fluorescent material. In the invention, wavelength conversion efficiency (internal quantum efficiency) is high, and the solar cell module is produced at comparatively low cost.

In the present embodiment as well the effects similar to the twenty-first embodiment are produced. Besides the organic fluorochrome, an inorganic fluorescent material (e.g., semiconductor nano fluorescent material) may be used.

In addition, colored resin having translucency can be used instead of transparent resin.

### Twenty-Third Embodiment

A twenty-third embodiment of the invention will be described. Description similar to the twenty-first embodiment is omitted. As illustrated in FIG. 17B, similar to the twenty-first embodiment, a solar cell module 3021 of the present embodiment is obtained as a result of attaching a solar cell 3023 on a wavelength conversion optical plate 3027 in a thickness direction of the plate 3027 with its end face 3025 obliquely cut.

The wavelength conversion optical plate 3027 of the present embodiment is obtained as a result of applying an organic fluorochrome on an upper surface of an optical glass plate 3029 which is made of high refractive index glass (refractive index: 1.7), for example, to form a translucent surface layer (organic fluorescent material layer) 3031.

For example, Pt (triphenylborane pyridine: TPBP) is used for this organic fluorochrome. This organic fluorochrome absorbs light with a wavelength that is equal to or smaller than 600 nm, and emits light with a wavelength of about 800 nm. Accordingly, in spectral characteristics of the solar cell 3023 made of an Si single crystal, a wavelength region of light in which more electricity is generated can be used.

In the invention, by applying the fluorescent material, for example, on the surface of the glass or resin base material, the fluorescent material layer is formed.

In the invention, the fluorescence (e.g., visible light whose ultraviolet region wavelength-light has been converted) generated as a result of the solar light reaching the fluorescent material on the base material surface enters into the transparent base material. The fluorescence is concentrated in the base material, and reflected on the base material end portion to enter into the solar cell.

In the present embodiment, the base material (optical glass plate 3029) itself need not have the wavelength changing function. Accordingly there is an advantage of the production of the solar cell module 3021 at comparatively low cost. For the fluorescent material applied to the surface of the optical glass plate 3029, for example, various kinds of fluorescent materials such as a semiconductor nano fluorescent material may be used other than the above-described organic fluorochrome.

### Twenty-Fourth Embodiment

A twenty-fourth embodiment of the invention will be described. Description similar to the twenty-first embodiment is omitted. As illustrated in FIG. 17C, similar to the twenty-first embodiment, a solar cell module 3041 of the present embodiment is obtained as a result of attaching a solar cell 3043 on a wavelength conversion optical plate 3045 in a thickness direction of the plate 3047 with its end face 3045 obliquely cut.

In the present embodiment, a translucent ultraviolet reflection preventing film 3049 that prevents reflection of light having an ultraviolet region wavelength (e.g., 300 nm to 400 nm; or 340 nm to 400 nm) is formed on the surface of the wavelength conversion optical plate 3047 on the sunray incident side.

For example, TiO₂, SiO₂, ZrO₂, or AlO₂ may be employed for a material of the ultraviolet reflection preventing film.

This ultraviolet reflection preventing film 3049 is made of a titanium dioxide (TiO₂) film and a silicon dioxide (SiO₂) film, for example, and formed by stacking them alternately through a vacuum evaporation method, for example. In the present embodiment, the ultraviolet reflection preventing film 3049 is formed on the surface of the wavelength conversion optical plate 3047. Accordingly, the ultraviolet rays can be efficiently made to enter into the wavelength conversion optical plate 3047. Therefore, the wavelength conversion is enhanced.

### Twenty-Fifth Embodiment

A twenty-fifth embodiment of the invention will be described. Description similar to the twenty-first embodiment is omitted. As illustrated in FIG. 17D, similar to the twenty-first embodiment, a solar cell module 3051 of the present embodiment is obtained as a result of attaching a solar cell 3053 on a wavelength conversion optical plate 3057 in a thickness direction of the plate 3057 with its end face 3055 obliquely cut.

In the present embodiment, a texture (surface shape) 3059 for irregular reflection is formed on a surface of the wavelength conversion optical plate 3057 on the solar cell 3053-side. More specifically, surface-roughing forming is performed upon a lower surface of the wavelength conversion optical plate 3057 to prevent the total reflection of light (i.e., to make the light reflect irregularly) in the wavelength conversion optical plate 3057.

Accordingly, in the present embodiment, the incident quantity of light from the lower surface of the wavelength conversion optical plate 3057 to the solar cell 3053 is increased.

### Twenty-Sixth Embodiment

A Twenty-sixth embodiment of the invention will be described. Description similar to the twenty-first embodiment is omitted. As illustrated in FIG. 17E, similar to the twenty-first embodiment, a solar cell module 3061 of the present embodiment is obtained as a result of attaching a solar cell 3063 on a wavelength conversion optical plate 3067 in a thickness direction of the plate 3067 with its end face 3065 obliquely cut.

In the present embodiment, a reflection preventing film 3069 that prevents total reflection of the light whose wavelength has been converted in the wavelength conversion optical plate 3067 (light having a fluorescence wavelength) is formed on the surface of the wavelength conversion optical plate 3067 on the solar cell 3063-side. This reflection preventing film 3069 is made of a TiO2 film and an SiO2 film, for example, and formed by stacking them alternately through a vacuum evaporation method, for example.

Accordingly, in the present embodiment, similar to the twenty-fifth embodiment, the incident quantity, of light from the lower surface of the wavelength conversion optical plate 3067 to the solar cell 3063 is increased.

### Twenty-Seventh Embodiment

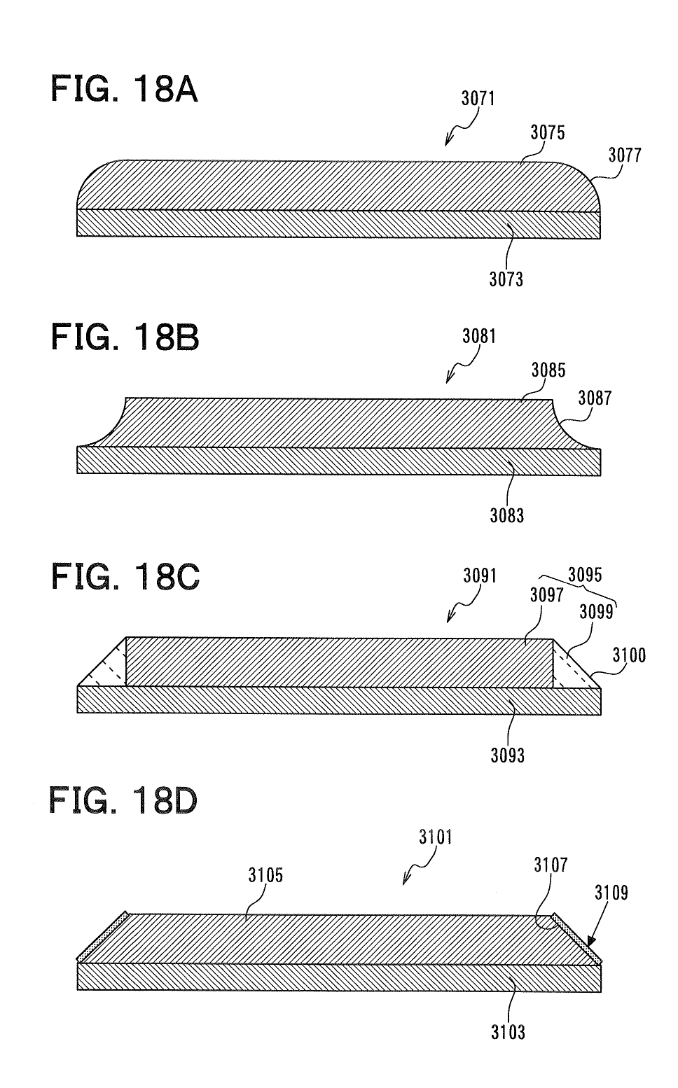

A twenty-seventh embodiment of the invention will be described. Description similar to the twenty-first embodiment is omitted. As illustrated in FIG. 18A, similar to the twenty-first embodiment, a solar cell module 3071 of the present embodiment is obtained as a result of attaching a solar cell 3073 on a wavelength conversion optical plate 3075 in a thickness direction of the plate 3075.

In the present embodiment, an end face 77 of the wavelength conversion optical plate 75 in a planar direction (right and left directions in FIG. 18A) of the plate 75 is formed in a curved surface which is crooked in an outwardly projecting shape. In the present embodiment, a line segment connecting upper and lower starting points of the curved surface in FIG. 18A is inclined relative to the planar direction. Accordingly, there is an advantage that light-concentrating capability improves compared to the case of the end face being perpendicular to the planar direction (further, compared to the case of the end face being a plane).

### Twenty-Eighth Embodiment

A twenty-eighth embodiment of the invention will be described. Description similar to the twenty-first embodiment is omitted. As illustrated in FIG. 18B, similar to the twenty-first embodiment, a solar cell module 3081 of the present embodiment is obtained as a result of attaching a solar cell 3083 on a wavelength conversion optical plate 3085 in a thickness direction of the plate 3085.

In the present embodiment, an end face 3087 of the wavelength conversion optical plate 3085 in a planar direction (right and left directions in FIG. 18B) of the plate 3085 is formed in a curved surface which is crooked in an outwardly recessed (inwardly projecting) shape. In the present embodiment, a line segment connecting upper and lower starting points of the curved surface in FIG. 18B is inclined relative to the planar direction. Accordingly, there is an advantage that light-concentrating capability improves compared to the case of the end face being perpendicular to the planar direction.

The invention illustrates the shape of the end face of the wavelength conversion optical plate. When this end face is constituted of a single plane, its structure is simple. Alternatively, this end face may be made up of more than one plane (e.g., more than one plane such that the inclined surface is outwardly projecting or inwardly projecting).

### Twenty-Ninth Embodiment

A twenty-ninth embodiment of the invention will be described. Description similar to the twenty-first embodiment is omitted. As illustrated in FIG. 18C, similar to the twenty-first embodiment, a solar cell module 3091 of the present embodiment is obtained as a result of attaching a solar cell 3093 on a wavelength conversion optical plate 3095 in a thickness direction of the plate 3095.

In the present embodiment, the wavelength conversion optical plate 3095 is constituted of a wavelength conversion board 3097 (having a wavelength changing function) whose end face is perpendicular to the planar direction, and a triangular prism-shaped transparent glass member 3099 (without having wavelength changing performance) attached on an end portion of the wavelength conversion board 3097 in its planar direction (four sides along the circumference of the board 3097).

In the present embodiment, when producing the wavelength conversion optical plate 3095, a member whose end face is perpendicular to the planar direction may be used for the wavelength conversion board 3097; and a triangular prism-shaped glass member (having three planar surfaces) (i.e., component whose two surfaces on the vertical end-face side and on the solar cell 3093-side are perpendicular to each other, and whose slanted end face is planar) 3099 may be attached on the end face of 3097. Accordingly, there is an advantage that the wavelength conversion optical plate 3095 with its end face 3100 inclined is easily produced.

In addition, a member having a wavelength changing function may be employed as the glass member 3099. Moreover, a similar-shaped resin member having translucency (e.g., transparent) may be used instead of the glass member 3099.

When producing the wavelength conversion optical plate whose end portion is in a projecting shape as in the twenty-seventh embodiment, a member whose two sides are perpendicular to each other and whose other one side is in a projecting shape may be employed for the triangular prism-shaped member. Similarly, when producing the wavelength conversion optical plate whose end portion is in a recessed shape as in the twenty-eighth embodiment, a member whose two sides are perpendicular to each other and whose other one side is in a recessed shape may be employed for the triangular prism-shaped member. In the invention, even though the end face of the wavelength conversion optical plate in its planar direction is a member that is perpendicular to the planar direction, by attaching a triangular prism-shaped glass or resin optical component (optical component whose two surfaces are perpendicular to each other and whose slanted end face is inclined in accordance with a flat surface, a projecting shape, and a recessed shape) on this end face, the wavelength conversion optical plate with its end portion inclined is easily produced.

### Thirtieth Embodiment

A thirtieth embodiment of the invention will be described. Description similar to the twenty-first embodiment is omitted. As illustrated in FIG. 18D, similar to the twenty-first embodiment, a solar cell module 3101 of the present embodiment is obtained as a result of attaching a solar cell 3103 on a wavelength conversion optical plate 3105 in a thickness direction of the plate 3105.

In the present embodiment a reflective film 3109 that reflects light is formed on an oblique end face 3107 of the wavelength conversion optical plate 3105 in its planar direction. This reflective film 3109 is made of aluminum (Al) having thickness of 100 nm, and may be formed by sputtering or evaporation coating.

As a result of such a reflective film 3109, the light whose wavelength is converted and the light which is totally reflected in the wavelength conversion optical plate 3105, are approximately 100% reflected on the oblique end face 3107. Accordingly, the light is concentrated efficiently into the solar cell 3103.

Thus, because of such a configuration, the amount of fluorescent light that is concentrated and entering, and the amount of totally reflected light are increased. Accordingly, the total conversion efficiency increases from 17.5% to 22%.

### Thirty-First Embodiment

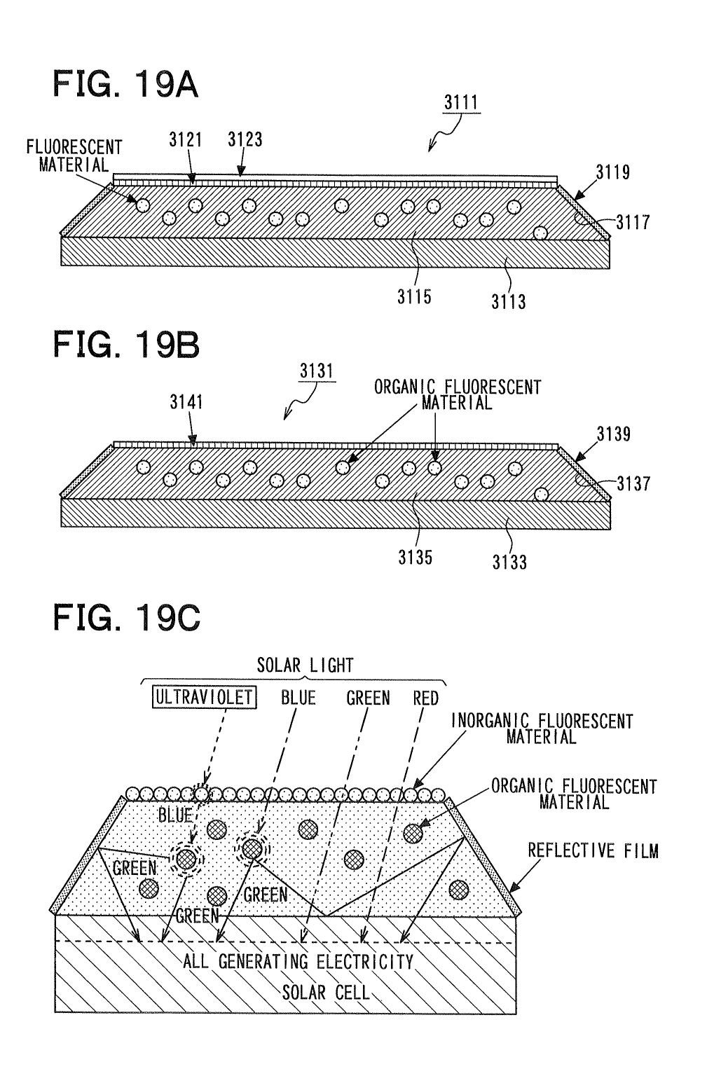

A thirty-first embodiment of the invention will be described. Description similar to the thirtieth embodiment is omitted. As illustrated in FIG. 19A, in a solar cell module 3111 of the present embodiment, similar to the thirtieth embodiment, a solar cell 3113 is attached on a wavelength conversion optical plate 3115 in a thickness direction of the plate 3115, and furthermore, a reflective film 3119 that reflects light is formed on an oblique end face 3117 of the wavelength conversion optical plate 3115 in its planar direction.

In the present embodiment, for example, an inorganic fluorescent material (Tb, Eu, Ce, Mn, Co, V, Sn, Cu, or Dy) is contained in the wavelength conversion optical plate 3115. In addition, on an incident side outer surface of the wavelength conversion optical plate 3115, the solar cell module 3111 includes for example, a fluorescent material layer 3121 that is formed as a result of applying the inorganic fluorescent material.

Furthermore, in the present embodiment, a protective plate 3123 made of transparent glass or resin, for example, is bonded by an optical adhesive on a surface of the fluorescent material layer 3121. In the present embodiment, the protective plate 3123 is attached to cover the fluorescent material layer 3121. Accordingly, there is an advantage that the fluorescent material layer 3121 does not exfoliate easily.

As illustrated in FIG. 14C, for example, the invention illustrates the fluorescent material (i.e., fluorescence active material that generates fluorescence under light). By using this fluorescent material, the solar light is stably wavelength-converted.

These inorganic matters exist as metal ions in the glass. In the resin, they exist as metal ions added to an oxide particle, for example.

### Thirty-Second Embodiment

A thirty-second embodiment of the invention will be described. Description similar to the thirtieth embodiment is omitted. As illustrated in FIG. 19B, in a solar cell module 3131 of the present embodiment, similar to the thirtieth embodiment, a solar cell 3133 is attached on a wavelength conversion optical plate 3135 in a thickness direction of the plate 3135, and furthermore, a reflective film 3139 that reflects light is formed on an oblique end face 3137 of the wavelength conversion optical plate 3135 in its planar direction.

In the present embodiment, for example, an organic fluorescent material that converts a blue light into a green light is contained in the wavelength conversion optical plate 3135. In addition, on an incident side-outer surface of the wavelength conversion optical plate 3135, the solar cell module 3131 includes, for example, an inorganic fluorescent material layer 3141, which is formed as a result of applying an inorganic fluorescent material that converts the ultraviolet rays into a blue light.

Accordingly, in the present embodiment, as schematically illustrated in FIG. 19C, ultraviolet rays of the solar light are converted into a blue light by the Inorganic fluorescent material on the surface of the wavelength conversion optical plate 3135. The blue light (and a blue light in the solar light) is converted into a green light by the organic fluorescent material in the wavelength conversion optical plate 3135. The green light (and a red light in the solar light) enters into the solar cell 3133. As a result, the solar light is efficiently converted into the electricity.

The organic fluorescent material easily deteriorates due to the ultraviolet rays. Nevertheless, in the present embodiment, the surface of the wavelength conversion optical Plate 3135 including the organic fluorescent material is covered with the inorganic fluorescent material layer 3141. Accordingly, the ultraviolet rays do not easily reach the organic fluorescent material. Therefore, there is an advantage that the organic fluorescent material does not deteriorate easily.

The organic fluorescent material in the base material easily deteriorates due to the ultraviolet rays of the solar light. However, in the invention, the inorganic fluorescent material layer is formed on the surface of the base material including the organic fluorescent material (on the solar light incident side), for example, by the application of the inorganic fluorescent material. Accordingly, the ultraviolet rays are blocked with the inorganic fluorescent material layer, so that the ultraviolet rays do not easily reach the organic fluorescent material. As a result, deterioration of the organic fluorescent material is prevented.

Moreover when the ultraviolet rays are wavelength-converted into a light such as blue by the inorganic fluorescent material, using this wavelength-converted light, the wavelength conversion is further performed into a light such as green through the organic fluorescent material. Thus, electricity is generated efficiently.

In addition, a fluorescent material such as Tb, Eu, Ce, Mn, Co, V, Sn, Cu, or Dy may be used for the inorganic fluorescent material. A material such as CdTe, CdSe, or ZnSe may be employed for the organic fluorescent material. When a flat surface shape of the wavelength conversion optical plate is a polygon which is a triangle or more, the solar cell module is arranged efficiently.

The embodiments of the invention have been described above, Nevertheless, the invention is not limited to the above-described specific embodiments and the invention may be embodied in the other various modes within the scope of the invention. For example, lights other than a solar light may be also employed.

Additional advantages and modifications will readily occur to those skilled in the art. The invention in its broader terms is therefore not limited to the specific details, representative apparatus, and illustrative examples shown and described.

What is claimed is:

1. A solar cell module comprising:
a solar cell having a shape of a flat plate; and
a wavelength conversion optical plate stacked on the solar cell such that the solar cell is attached on the optical plate in a thickness direction of the optical plate, the optical plate configured to convert wavelength of solar light, wherein an end portion of the optical plate in a planar direction of the optical plate has an end face which is inclined relative to the planar direction, so that light, whose wavelength is converted in the optical plate, enters into the solar cell.

2. The solar cell module according to claim 1, wherein the inclined end face of the optical plate in the planar direction is a flat surface.

3. The solar cell module according to claim 1, wherein the inclined end face of the optical plate in the planar direction includes an outwardly projecting curved surface.

4. The solar cell module according to claim 1, wherein the inclined end face of the optical plate in the planar direction includes an inwardly recessed curved surface.

5. The solar cell module according to claim 1, further comprising a reflective film on the inclined end face of the optical plate in the planar direction, wherein the reflective film reflects light.

6. The solar cell module according to claim 1, further comprising a member that has a shape of a triangular prism and is made of glass or resin, wherein:
the member is attached on the end portion of the optical plate in the planar direction; and
a surface of the member that is exposed to an outside of the module is inclined relative to the planar direction.

7. The solar cell module according to claim 1, further comprising an ultraviolet reflection preventing film on a surface of the optical plate on a solar-light entering side of the optical plate, wherein the ultraviolet reflection preventing film is configured to prevent reflection of light having an ultraviolet region wavelength.

8. The solar cell module according to claim 1, further comprising a texture for irregular reflection, on a solar cell-side surface of the optical plate.

9. The solar cell module according to claim 1, further comprising a reflection preventing film on a solar cell-side surface of the optical plate, wherein the reflection preventing film is configured to prevent reflection of light, whose wavelength is converted in the optical plate.

10. The solar cell module according to claim 1, wherein:
the optical plate is made of one of transparent glass and transparent resin, and includes a fluorescent material in the one of glass and resin; and
the fluorescent material generates fluorescence in accordance with solar light which enters into the optical plate.

11. The solar cell module according to claim 10, wherein the fluorescent material is made of at least one of Tb, Eu, Ce, Mn, Co, V, Sn, Cu, and Dy.

12. The solar cell module according to claim 10, wherein the fluorescent material is a semiconductor nano fluorescent material, which includes at least one of CdTe, CdSe, and ZnSe.

13. The solar cell module according to claim 10, wherein:
the fluorescent material is an organic fluorescent material; and
the optical plate is made of transparent resin.

14. The solar cell module according to claim 1, wherein:
the optical plate includes:
a base material made of one of transparent glass and transparent resin; and
a fluorescent material layer on a surface of the base material, which is on an opposite side from the solar cell; and
the fluorescent material layer includes a fluorescent material that generates fluorescence in accordance with solar light which enters into the optical plate.

15. The solar cell module according to claim 14, wherein the fluorescent material is made of at least one of Tb, Eu, Ce, Mn, Co, V, Sn, Cu, and Dy.

16. The solar cell module according to claim 14, wherein the fluorescent material is a semiconductor nano fluorescent material, which includes at least one of CdTe, CdSe, and ZnSe.

17. The solar cell module according to claim 14, wherein:
the fluorescent material is an, organic fluorescent material; and
the optical plate is made of transparent resin.

18. The solar cell module according to claim 1, wherein the optical plate includes:
a base material made of transparent resin, the resin including an organic fluorescent material; and
an inorganic fluorescent material layer on a surface of the base material, which is on an opposite side from the solar cell, the inorganic fluorescent material layer including an inorganic fluorescent material that generates fluorescence in accordance with solar light which enters into the optical plate.

19. The solar cell module according to claim 1, wherein the solar cell includes:
a first solar cell disposed on an outer perimeter part of a surface of the optical plate in the thickness direction, wherein light, which reflects on the inclined end face of the optical plate, is emitted toward the outer perimeter part; and
a second solar cell disposed inward of the outer perimeter part, wherein the first solar cell has higher sensitivity for the light, whose wavelength is converted, than the second solar cell.

20. The solar cell module according to claim 19, wherein:
the optical plate includes:
a base material configured to convert wavelength of solar light; and
a member that has a shape of a triangular prism and is attached on an end portion of the base material in a planar direction of the base material, the member being made of glass or resin; and
an end face of the member in the planar direction of the base material serves as the inclined end face of the optical plate.

21. The solar cell module according to claim 1, wherein:
the solar cell is disposed on an outer perimeter part of a surface of the optical plate in the thickness direction, wherein light, which reflects on the inclined end face of the optical plate, is emitted toward the outer perimeter part; and
the outer perimeter part defines an empty space part inward of the outer perimeter part, no solar cell disposed in the empty space part.

22. The solar cell module according to claim 21, wherein:
the optical plate includes:
a base material configured to convert wavelength of solar light; and
a member that has a shape of a triangular prism and is attached on an end portion of the base material in a planar direction of the base material, the member being made of glass or resin; and
an end face of the member in the planar direction of the base material serves as the inclined end face of the optical plate.

23. The solar cell module according to claim 1, wherein:
the optical plate is one of a plurality of wavelength conversion optical plates that are stacked one after another in a thickness direction of each of the plurality of optical plates; and
the plurality of optical plates are configured to convert different wavelengths of solar light.

24. The solar cell module according to claim 23, wherein:
the plurality of optical plates include:
a blue wavelength conversion optical plate configured to convert ultraviolet light into blue light;
a green wavelength conversion optical plate configured to convert ultraviolet light into green light; and
a red wavelength conversion optical plate configured to convert ultraviolet light into red light; and
the blue optical plate, the green optical plate, and the red optical plate are stacked in this order from a solar-light entering side thereof.

25. The solar cell module according to claim 23, further comprising one of:
a space between each adjacent two of the plurality of optical plates, the space having thickness of 1 μm to 1 mm; and
an intermediate layer between each adjacent two of the plurality of optical plates, the intermediate layer having a refractive index that is different from its adjacent two of the plurality of optical plates.

26. The solar cell module according to claim 23, wherein:
the solar cell is one of a plurality of solar cells;
the plurality of solar cells are arranged, such that each light having a corresponding wavelength is converted in a corresponding one of the plurality of optical plates, and reflects on a corresponding inclined end face, to be received by a corresponding one of the plurality of solar cells; and
each of the plurality of solar cells has higher sensitivity for a corresponding wavelength than sensitivity for any other wavelength.

27. The solar cell module according to claim 26, wherein:
the plurality of optical plates serve as a stacked member; and
the plurality of solar cells, each of which has higher sensitivity for a corresponding wavelength, are arranged on an outer perimeter part of a surface of the stacked member, the module further comprising another solar cell disposed inward of the outer perimeter part, the another solar cell having a different sensitivity from the plurality of solar cells.

28. The solar cell module according to claim 23, wherein the plurality of optical plates serve as a stacked member, the module further comprising a reflective film, which reflects light, on the inclined end face of the stacked member in a planar direction of the stacked member.

29. A solar cell module comprising:
a wavelength conversion optical plate configured to convert wavelength of solar light, wherein an end portion of the optical plate in a planar direction of the optical plate has an end face which is inclined relative to the planar direction; and
a solar cell that has a shape of a flat plate and that is attached on a surface of the inclined end face of the optical plate.

30. The solar cell module according to claim 29, wherein:
the optical plate includes:
a base material configured to convert wavelength of solar light; and
a member that has a shape of a triangular prism and is attached on an end portion of the base material in a planar direction of, the base material, the member being made of glass or resin; and
an end face of the member in the planar direction of the base material serves as the inclined end face of the optical plate.

31. The solar cell module according to claim 29, further comprising a reflective film that reflects light, wherein:
the reflective film is provided on an outer perimeter part of a surface of the optical plate in a thickness direction of the optical plate; and
the outer perimeter part is on an opposite side from the inclined end face of the optical plate in the thickness direction, and opposed to the inclined end face of the optical plate.

32. The solar cell module according to claim 29, further comprising another solar cell, wherein:
the another solar cell is provided on an outer perimeter part of a surface of the optical plate in a thickness direction of the optical plate; and
the outer perimeter part is on an opposite side from the inclined end face of the optical plate in the thickness direction, and opposed to the inclined end face of the optical plate.

33. The solar cell module according to claim 29, further comprising another solar cell on an entire surface of the optical plate, which is on an opposite side from the inclined end face of the optical plate in the thickness direction.

34. A plate-shaped solar panel comprising:
a frame; and
a plurality of solar cell modules arranged in the frame in a planar direction of the frame, wherein:
each of the plurality of solar cell modules includes:
a solar cell having a shape of a flat plate; and
a wavelength conversion optical plate stacked on the solar cell such that the solar cell is attached on the optical plate in a thickness direction of the optical plate, the optical plate configured to convert wavelength of solar light;
an end portion of the optical plate in a planar direction of the optical plate has an end face which is inclined relative to the planar direction, so that light, whose wavelength is converted in the optical plate, enters into the solar cell; and
the frame includes a fixing part, to which an end portion of each of the plurality of solar cell modules in a planar direction thereof is fixed in a state where each of the plurality of solar cell modules is arranged at a corresponding predetermined fixing position of the frame.

35. The solar panel according to claim 34, wherein the frame further includes a wiring that is electrically connected to an electrode of the solar cell.

36. The solar panel according to claim 34, wherein the fixing part is engaged with the inclined end face of the optical plate and with a surface of the solar cell on an opposite side from a light entering side of the solar cell.

37. The solar panel according to claim 36, wherein the fixing part includes an inclined end face that is in contact with the inclined end face of the optical plate.

38. The solar panel according to claim 34, wherein the frame includes:
an upper frame that fixes the optical plate from a light entering side thereof; and
a lower frame that fixes the solar cell from an opposite side from a light entering side of the solar cell.

39. The solar panel according to claim 34, further comprising an auxiliary wavelength conversion optical plate on a surface of the frame on a solar light entering side thereof, wherein light enters into the optical plate through the auxiliary optical plate.

40. The solar panel according to claim 34, further comprising a reflective member disposed between each adjacent two of the plurality of solar cell modules, wherein the reflective member reflects solar light toward the end portion of the optical plate in the planar direction.

41. The solar panel according to claim 34, further comprising a fin for cooling on a surface of the frame on an opposite side from a solar light entering side of the frame.

42. The solar panel according to claim 41, further comprising a thermoelectric element between the frame and the fin.

43. The solar panel according to claim 34, further comprising one of a translucent protective sheet and a translucent protective plate covering the plurality of solar cell modules and all or part of the frame.

44. The solar panel according to claim 34, further comprising one of a translucent protective sheet and a translucent protective plate covering each of the plurality of solar cell modules, wherein each of the plurality of solar cell modules covered with the one of the protective sheet and the protective plate is fixed in the frame.
